(19) United States
(12) Patent Application Publication
(10) Pub. No.: US 2008/0290472 A1
(43) Pub. Date: Nov. 27, 2008

(54) SEMICONDUCTOR INTERLAYER-INSULATING FILM FORMING COMPOSITION, PREPARATION METHOD THEREOF, FILM FORMING METHOD, AND SEMICONDUCTOR DEVICE

(75) Inventors: Fujio Yagihashi, Joetsu-shi (JP); Yoshitaka Hamada, Joetsu-shi (JP); Takeshi Asano, Joetsu-shi (JP); Tsutomu Ogihara, Joetsu-shi (JP); Motoaki Iwabuchi, Joetsu-shi (JP); Hideo Nakagawa, Shiga (JP); Masaru Sasago, Osaka (JP)

Correspondence Address: MYERS BIGEL SIBLEY & SAJOVEC, PO BOX 37428, RALEIGH, NC, 27627, US

(73) Assignees: Shin Etsu Chemical Co., Ltd.; Matsushita Electric Industrial Co., Ltd.

(21) Appl. No.: 12/029,562

(22) Filed: Feb. 12, 2008

(30) Foreign Application Priority Data
Feb. 16, 2007 (JP) 2007-036343

(51) Int. Cl. H01L 23/58; C08K 3/34; C08K 3/36; B32B 5/18; H01L 21/312

(52) U.S. Cl. 257/632; 524/588; 524/450; 428/304.4; 438/781; 257/E23.002; 257/E21.26

(57) ABSTRACT

Provided is a porous-film-forming composition containing silicon-oxide-based fine particles and a polysiloxane compound obtained by hydrolysis and condensation reactions, in the presence of an acid catalyst, of a hydrolyzable silane compound containing at least one tetrafunctional alkoxysilane compound represented by the following formula (1):

Si(OR¹)₄ (1)

wherein, R¹s may be the same or different and each independently represents a linear or branched C₁₋₄ alkyl group and/or at least one alkoxysilane compound represented by the following formula (2):

R²ₙSi(OR³)₄₋ₙ (2)

wherein, R²(s) may be the same or different when there are plural R²s and each independently represents a linear or branched C₁₋₈ alkyl group, R³(s) may be the same or different when there are plural R³s and each independently represents a linear or branched C₁₋₄ alkyl group, and n is an integer from 1 to 3 in the reaction mixture containing a large excess of water.

### CROSS-RELATED APPLICATIONS

This application claims priority from Japanese Patent Application No. 2007-036343; filed Feb. 16, 2007, the disclosure of which is incorporated herein by reference in its entirety.

### BACKGROUND OF THE INVENTION

1. Field of the Invention

The present invention relates to a film forming composition capable of providing a porous film excellent in dielectric properties and mechanical strength, a method for forming a porous film, a porous film thus formed, and a semiconductor device having therein the porous film.

2. Description of the Related Art

In the fabrication of semiconductor integrated circuits, as their integration degree becomes higher, an increase in interconnect delay time due to an increase in interconnect capacitance, which is a parasitic capacitance between metal interconnects, prevents their performance enhancement. The interconnect delay time is called an RC delay which is in proportion to the product of electric resistance of metal interconnects and the static capacitance between interconnects. A reduction in the resistance of metal interconnects or a reduction in the capacitance between interconnects is necessary for reducing this interconnect delay time.

The reduction in the resistance of an interconnect metal or the interconnect capacitance can prevent even a highly integrated semiconductor device from causing an interconnect delay, which enables miniaturization and high speed operation of the semiconductor device and moreover, reduction of the power consumption.

In order to reduce the resistance of metal interconnects, copper interconnects have recently replaced conventional aluminum interconnects in semiconductor device structure. Use of copper interconnects alone, however, has limits in accomplishing performance enhancement so that the reduction in the interconnect capacitance is an urgent necessity for further performance enhancement of semiconductor devices.

In order to reduce the capacitance between interconnects, one method may be to decrease dielectric constant of an interlayer insulating film formed between metal interconnects. In order to form a material having a dielectric constant of 2.5 or less, it is the common practice to introduce pores into the material to make it porous.

The material which is made porous however inevitably provides a film having deteriorated mechanical strength, which poses a serious problem in the manufacture of a semiconductor device. In addition, deterioration in the mechanical strength of the film results in the insufficient strength of the semiconductor device itself, leading to deterioration in the reliability of the device. It is therefore necessary and indispensable to develop a low dielectric constant material satisfying both a low dielectric constant and high mechanical strength.

Roughly speaking, two methods are known for forming an interlayer insulating film, that is, chemical vapor deposition and coating method. Each method has advantages and disadvantages. Chemical vapor deposition is suited for forming a film having a dielectric constant of 2.6 or greater, while the coating method is advantageous for forming a film having a dielectric constant not greater than 2.6. Among coating materials, those having silicon oxide in main chain are promising as next-generation insulating materials rather than organic materials because the former ones can be made porous relatively easily. Materials used conventionally in the coating method cannot satisfy both a low dielectric constant and mechanical strength necessary for the manufacture of semiconductor devices.

For improving the mechanical strength of a porous film, there is an attempt to incorporate fine particles in the film. For example, Japanese Patent Provisional Publication No. 315812/1997 discloses a method of forming a porous film by using a material obtained by bonding, to silica fine particles, a silicon-oxide-based side chain partially substituted with hydrogen or alkyl group. In addition, Japanese Patent Provisional Publication No. 2004-165402 discloses a method of bonding, to zeolite or silica fine particles, a silicon-oxide-based side chain partially substituted with an alkyl group and then carrying out treatment capable of keeping high crosslinking activity of the side chain during film formation.

### SUMMARY OF THE INVENTION

A number of attempts to develop materials for forming a low-dielectric-constant insulating film having both a low dielectric constant and high mechanical strength including the above-described technologies have been made, but materials capable of satisfying both of them have not yet been found. For example, in an attempt to use zeolite fine particles, the mechanical strength of the film is much inferior to that expected from the mechanical strength of zeolite itself so that a new breakthrough is necessary for incorporating fine particles in a film, thereby increasing the mechanical strength thereof.

With the foregoing in view, one object of the present invention is to provide a novel coating solution for forming porous-film which can easily provide, by a method ordinarily employed in a conventional semiconductor manufacturing method, a thin film having a freely controlled thickness and excellent in both mechanical strength and dielectric properties. Another object of the invention is to provide a high-performance and high-reliability semiconductor device having therein the porous film.

The present inventors have carried out an extensive investigation with a purpose of developing a coating solution for forming porous-film having the above-described properties. As one attempt, they make a working hypothesis that if a bond between silicon-oxide-based fine particles constituting the skeleton of a porous film can be reinforced at a soft sintering step before sintering, shrinkage of the film during sintering can be suppressed and a sufficient porosity can be maintained by spaces formed between these particles; and since the skeleton is not broken, the porous film can have improved mechanical strength. They searched for materials capable of reinforcing the bond between particles and serving as a so-called adhesive.

Japanese Patent Provisional Publication No. 71654/1997 discloses a material capable of providing a film having high pencil hardness for the use of hard coating on plastics. This material is characterized by that it uses a silicon oxide-based polymer having many silanol groups. The inventors think that use of such a material will enable reinforcement of a bond between silicon-oxide-based fine particles due to an Si—O—Si bond formed newly with the surface of silicon-oxide-based fine particles by making use of silanol. They prepare a polysiloxane resin containing silanol groups at high concentration by a method obtained by modifying a preparation method of the material disclosed in Japanese Patent Provisional Publication No. 71654/1997 and incorporate both the resin and the fine particles into a composition. As a result, it has been found that a film having a low dielectric constant but showing a markedly high mechanical strength can be formed as is expected, leading to the completion of the invention.

In one aspect of the invention, there may be thus provided a porous-film-forming composition comprising a silicon-oxide-based fine particles and a polysiloxane compound capable of forming a silicon-oxygen-silicon bond between the fine particles through condensation during film formation, thereby improving the strength of a skeleton formed by the fine particles.

A film containing silicon-oxide-based fine particles has mechanical strength due to the skeleton structure formed by the fine particles. An addition, to the fine particles, of a material capable of forming a silicon-oxide-silicon bond between fine particles and fixing positions thereof by heating enables reinforcement of the skeleton formed by the fine particles. As a result, a film having high mechanical strength can be obtained.

Specifically, polysiloxane compounds may be available by hydrolyzing and condensing, in the presence of an acid catalyst, a hydrolyzable silane compound containing at least one tetrafunctional alkoxysilane compound represented by the following formula (1):

Si(OR¹)₄ (1)

(wherein, R¹s may be the same or different and each independently represents a linear or branched C₁₋₄ alkyl group) and/or at least one alkoxysilane compound represented by the following formula (2):

R²ₙSi(OR³)₄₋ₙ (2)

(wherein, R²(s) may be the same or different when there are plural R²s and each independently represents a linear or branched C₁₋₈ alkyl group, R³(s) may be the same or different when there are plural R³s and each independently represents a linear or branched C₁₋₄ alkyl group, and n is an integer from 1 to 3), while hydrating silanol groups generated during the reaction so as to control the condensation reaction and suppress gelation.

The polysiloxane compound obtained by the above-described method may have a relatively strong skeleton and a high concentration of silanol groups. Silanol groups may have a high condensation reactivity. Also, silanol group tends to cause interaction and condensation reactions with a silicon-oxide-based fine particle. Accordingly, a crosslinking reaction may be progressing even at a relatively low temperature stage where a solvent still remains. The crosslinking reaction may contribute to reinforcement of a film structure. The silanol groups may be on the other hand stabilized by hydration. Hydrated water molecules may tend to cause an interaction with the silicon-oxide-based fine particles and this interaction may efficiently promote the progress of condensation and crosslinking reactions when water molecules disappear by heating. By these reactions, the silicon-oxide-based fine particles may be crosslinked firmly during a coating step and a film formation step and a high-strength film having pores retained therein can be obtained.

In order to carry out hydrolysis and condensation reactions in the presence of an acid catalyst while hydrating the silanol groups generated during the hydrolysis reaction so as to control the condensation reaction and so as to suppress gelation, one possible method may be to include a step of adding the hydrolyzable silane compound to a hydrolysis reaction mixture which constantly contains water in an amount exceeding a molar equivalent of the hydrolyzable group in the hydrolyzable silane compound which has already been charged. By the dropwise addition of the hydrolyzable silane compound to the hydrolysis reaction mixture in which the reaction still continues and water is contained in an amount exceeding the molar equivalent of the hydrolyzable group, it may be possible to obtain a polysiloxane compound having a high concentration of silanol groups and therefore useful for the composition of the invention while hydrating the silanol groups generated by the hydrolysis and suppressing gelation.

It may be preferred to hydrolyze and condense the polysiloxane compound in a reaction mixture containing water in an amount of 5 moles or greater per mole of the reactive silicon-oxygen bonds in the hydrolyzable silane mixture. A polysiloxane compound with a high-concentration of silanol groups may be obtained without causing gelation under this condition.

The polysiloxane compound may be preferably composed of units represented by the following formulas (Q1 to 4, T1 to 3) and satisfies the following relationships supposing that the molar ratio of each unit in the polysiloxane compound be q1, q2, q3, q4, t1, t2, and t3, respectively:

(q1+q2+t1)/(q1+q2+q3+q4+t1+t2+t3)≦0.2 and

(q3+t2)/(q1+q2+q3+q4+t1+t2+t3)≧0.4

When the molar ratios of the units satisfy the above-described ranges, high crosslinking activity can be accomplished. The molar ratios of the units in the polysiloxane compound can be determined by ²⁹Si—NMR measurement.

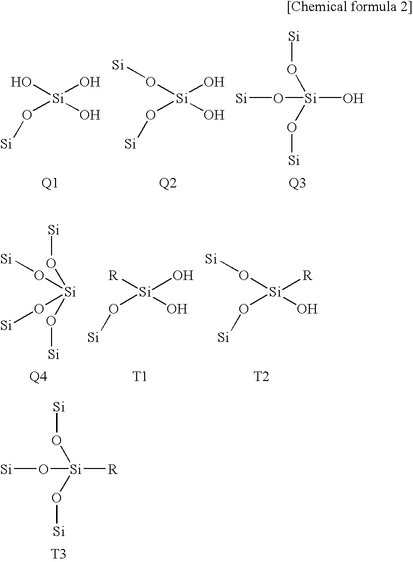

Zeolite fine particles including zeolite seed crystals can be given as one mode of the silicon-oxide-based fine particles. Since zeolite fine particles have a regularly repeated structure of oxygen and silicon, they can provide high strength due to their crystallinity. A film having high strength can be obtained by reinforcing the bonds between fine particles.

As the zeolite fine particles, those obtained by modifying zeolite with a hydrolyzable silane as a crosslinkable side chain can also be used. The crosslinkable side chain can improve the reactivity with the polysiloxane compound.

Examples of the silicon-oxide-based fine particles contained in the composition of the invention may include silica fine particles. Silica fine particles may be inferior to zeolite fine particles in hardness, but they can be prepared advantageously by an industrial process and they can have preferably physical properties according to an easy introduction design of an organic group.

The silica fine particles are preferably those obtained by hydrolyzing and condensing, in the presence of an alkaline catalyst, a hydrolyzable silane compound containing at least one tetrafunctional alkoxysilane compound represented by the following formula (3):

Si(OR⁴)₄ (3)

(wherein, four R⁴s may be the same or different and each independently represents a linear or branched C₁₋₄ alkyl group) and at least one alkoxysilane compound represented by the following formula (4):

R⁵ₘSi(OR⁶)₄₋ₘ (4)

(wherein, R⁶(s) may be the same or different when there are plural R⁶s and each independently represents a linear or branched C₁₋₄ alkyl group, R⁵(s) may be the same or different when there are plural R⁵s and each independently represents a linear or branched C₁₋₈ alkyl group which may optionally contain any substituents, and m is an integer from 1 to 3). Contamination of impurities such as metals and halogens can be suppressed by using the above-described raw materials as a main silicon source.

In the above-described synthesis method of silica fine particles to be used for the composition of the invention and available by the above-described hydrolysis and condensation reactions, it is more preferred to use, as the alkaline catalyst used for hydrolysis and condensation reactions, a mixture of

at least one hydrophilic basic catalyst selected from the group consisting of alkali metal hydroxides and quaternary ammonium hydroxides represented by the following formula (5):

(R⁷)₄N⁺OH⁻ (5)

(wherein, R⁷s may be the same or different and each independently represents an organic group composed of carbon, hydrogen and oxygen and the cationic portion [(R⁷)₄N⁺] satisfies the following relationship (6):

(N+O)/(N+O+C)≧⅕ (6)

in which, N, O and C are the numbers of nitrogen, oxygen and carbon atoms contained in the cationic portion, respectively), and
at least one hydrophobic basic catalyst selected from quaternary ammonium hydroxides which do not satisfy the above-described relationship (6). The silica fine particles obtained under the above-described conditions may have especially high strength so that combined use of them with the polysiloxane compound can yield a porous-film-forming composition capable of providing especially good mechanical strength.

In the above-described synthesis method of silica fine particles to be used for the composition of the invention and available by the hydrolysis and condensation reactions, it is also more preferred to use, as at least a portion of the alkaline catalyst, a salt of a silsesquioxane cage compound represented by the following formula (7):

(SiO_{1.5}—O)ₚ^{p-}(X⁺)ₚ (7)

(wherein, X represents NR₄, Rs may be the same or different and each independently represents a linear or branched C₁₋₄ alkyl group and p is an integer from 6 to 24) which has been prepared in advance. The silica fine particles obtained under the above-described conditions may have especially high strength so that combined use of them with the polysiloxane compound can yield a porous-film-forming composition capable of providing especially good mechanical strength.

In another aspect of the invention, there is also provided a porous film obtained by applying the porous-film-forming composition onto a substrate and then sintering. In a further aspect of the invention, there is also provided a method for forming a porous silicon-containing film, which comprises applying the above-described composition onto a substrate to form a thin film, and then sintering the thin film.

In a still further aspect of the invention, there is also provided, as one of the uses of the porous-film-forming composition, a semiconductor device comprising, as a low-dielectric-constant insulating film, a porous silicon-containing film obtained by applying the composition onto a substrate and then sintering the coating. In a still further aspect of the invention, there is also provided a method for manufacturing a semiconductor device, which comprises applying the composition onto a substrate having a metal interconnect layer to form a thin film and then sintering the thin film.

In a still further aspect of the invention, there is also provided a method for preparing a porous-film-forming composition comprising the steps of:

obtaining a polysiloxane compound by hydrolysis and condensation reactions, in the presence of an acid catalyst, of a hydrolyzable silane compound containing at least one tetrafunctional alkoxysilane compound represented by the following formula (1):

Si(OR¹)₄ (1)

(wherein, R¹s may be the same or different and each independently represents a linear or branched C₁₋₄ alkyl group) and/or at least one alkoxysilane compound represented by the following formula (2):

R²ₙSi(OR³)₄₋ₙ (2)

(wherein, R²(s) may be the same or different when there are plural R²s and each independently represents a linear or branched C₁₋₈ alkyl group, R³(s) may be the same or different when there are plural R³s and each independently represents a linear or branched C₁₋₄ alkyl group, and n is an integer from 1 to 3) while hydrating silanol groups generated during the reaction to control the condensation reaction and suppress gelation;

extracting the polysiloxane compound with an organic solvent; and then

mixing the resulting polysiloxane compound with silicon-oxide-based fine particles.

Use of the porous-film-forming composition of the invention enables formation of a porous film excellent in both dielectric properties and mechanical strength. Moreover, the porous film of the invention is excellent in both dielectric properties and mechanical strength so that a semiconductor device having high reliability can be manufactured using the porous film.

### BRIEF DESCRIPTION OF THE DRAWINGS

FIG. 1 is a schematic cross-sectional view of one example of the semiconductor device according to the invention;

FIG. 2 is a ²⁹Si—NMR spectrum of each of the polysiloxane compounds obtained by respectively different processes while suppressing gelation;

FIG. 3 is a graph which plots the dielectric constant and mechanical strength controlled by changing the surface modification time of zeolite fine particles; and

FIG. 4 is a graph which plots the dielectric constant and mechanical strength controlled by changing the surface modification time of silica fine particles.

### DETAILED DESCRIPTION OF THE PREFERRED EMBODIMENT(S)

The present invention now will be described more fully hereinafter in which embodiments of the invention are provided with reference to the accompanying drawings. This invention may, however, be embodied in many different forms and should not be construed as limited to the embodiments set forth herein; rather, these embodiments are provided so that this disclosure will be thorough and complete, and will fully convey the scope of the invention to those skilled in the art.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise.

Unless otherwise defined, all technical and scientific terms used herein have the same meaning as commonly understood by one of ordinary skill in the art to which this invention belongs.

Hereinafter, preferred embodiments of the present invention will be described. However, it is to be understood that the present invention is not limited thereto.

The porous-film-forming composition of the invention is formed based on a model for achieving a low dielectric constant by combining the silicon-oxide-based fine particles together serving as a principal material in a film to form a structure portion, bonding the fine particles each other with the polysiloxane compound to reinforce the strength of the skeleton, and forming pores from spaces between the fine particles. Important factors in this model are that the fine particles themselves are resistant to an external force and combined fine particles constitute a sufficient bond at an early stage of sintering, thereby suppressing a reduction in porosity due to rearrangement of the fine particles and forming a strong bond. Even application of an external force after sintering does not change the positions of the fine particles.

In a model of a porous film for forming the pores from the spaces of the fine particles, thereby raising the mechanical strength, use of silicon-oxide-based fine particles which are presumed to have high mechanical strength is preferred. Examples of such fine particles include zeolite fine particles having a crystalline atomic arrangement and silica fine particles synthesized using an alkaline catalyst capable of easily raising an Si—O—Si bond density. In particular, use of zeolite fine particles can be expected to highly increase the mechanical strength of the film if the mechanical strength of the film resulted only from the strength of the fine particles, but actually an increase is not so high as expected. This is because although the fine particles have sufficient strength, application of an external force changes the position of the fine particles, whereby the strength of the film itself does not become so high. In the invention, for the purpose of suppressing movement of these fine particles, sufficient oxygen-silicon-oxygen bonds are formed between particles and positions of the particles are fixed at an early stage by heating after a film is formed by the coating method, whereby a reduction in the porosity during sintering is suppressed and a film having improved mechanical strength is obtained. In order to strongly fix the positions of the fine particles at an early stage, a material forming a bond with the silicon-oxide-based fine particles must contain a large amount of silanol groups having a high reaction activity. The material itself must have a certain level of strength in order to suppress a reduction in the porosity during sintering. As such a material, a polysiloxane compound which is synthesized under specific conditions in the presence of an acid catalyst and will be described later is preferred.

A composition containing a polysiloxane material obtained by hydrolysis and condensation reactions, in the presence of an acid catalyst, of a silica material which has been obtained by hydrolysis and condensation reactions in the presence of an alkali catalyst is already proposed in Japanese Patent Provisional Publication No. 2001-164186. A technology disclosed in this document does not include a concept that the strength of a film is attributable to the skeleton made by particles and it overlooks the importance of a strong bond formed between particles. Although a method using an acid catalyst is disclosed, the material disclosed therein is, different from a polysiloxane compound which is to be used in the invention and will be described later, obtained by a conventional method for preventing gelation at the time of hydrolysis and condensation reactions.

The polysiloxane compound contained in the porous-film-forming composition of the invention is characterized by having a high concentration of silanol groups and is synthesized in the following manner. A silicon compound serving as a starting material is a hydrolyzable silane compound containing at least one tetrafunctional alkoxysilane compound represented by the following formula (1) and/or at least one alkoxysilane compound represented by the following formula (2), or a mixture of the hydrolyzable silane compounds.

Si(OR¹)₄ (1)

R²ₙSi(OR³)₄₋ₙ (2)

(wherein, R¹s may be the same or different and each independently represents a linear or branched C₁₋₄ alkyl group, R²(s) may be the same or different when there are plural R²s and each independently represents a linear or branched C₁₋₈ alkyl group, R³(s) may be the same or different when there are plural R³s and each independently represents a linear or branched C₁₋₄ alkyl group, and n is an integer from 1 to 3).

A proportion of the compound of the formula (1) is, in terms of silicon atoms, preferably 25 mole % or greater but not greater than 100 mole %, more preferably 30 mole % or greater but not greater than 70 mole %, based on the total moles of the hydrolyzable silane compound(s) to be subjected to hydrolysis and condensation reactions in the presence of an acid catalyst. A proportion of the compound of the formula (2) is, in terms of silicon atoms, preferably 0 mole % or greater but not greater than 70 mole %, more preferably 5 mole % or greater but not greater than 60 mole %, based on the total moles of the hydrolyzable silane compound(s).

Preferred examples of R² of the silane compound (2) include alkyl groups such as methyl, ethyl, n-propyl, iso-propyl, n-butyl, iso-butyl, sec-butyl, t-butyl, n-pentyl, 2-ethylbutyl, 3-ethylbutyl, 2,2-diethylpropyl, cyclopentyl, n-hexyl and cyclohexyl, alkenyl groups such as vinyl and allyl, alkynyl groups such as ethynyl, aryl groups such as phenyl and tolyl, aralkyl groups such as benzyl and phenethyl, and other unsubstituted monovalent hydrocarbon groups. They may each have a substituent such as fluorine. Of these, methyl, ethyl, n-propyl, iso-propyl, vinyl and phenyl groups are especially preferred.

As R¹ and R³, those providing an alcohol, which appears as a by-product after hydrolysis, having a boiling point lower than that of water are preferred. Examples include methyl, ethyl, n-propyl and iso-propyl.

The hydrolyzable silane compound to be subjected to hydrolysis and condensation reactions may contain another silane in addition to those of the formulas (1) and (2). Examples of such a silane include dimethyldimethoxysilane, dimethyldiethoxysilane, hexamethoxydisiloxane, methylenebistrimethoxysilane, methylenebistriethoxysilane, 1,3-propylenebistrimethoxysilane, 1,4-bistrimethoxysilane and 1,4-phenylenebistrimethoxysilane. They may be added as an auxiliary component. Their amount is however adjusted to preferably 20% or less.

Methods for obtaining a siloxane polymer by hydrolysis and condensation reactions of the hydrolyzable silane compound in the presence of an acid catalyst can be classified into the following two methods, depending on the reaction control system. In the hydrolysis and condensation reactions of the hydrolyzable silane compound in the presence of an acid catalyst, a hydrolysis speed is higher than a condensation speed so that when a trivalent or tetravalent hydrolyzable silane compound is used as a raw material, the concentration of active silanol groups in the reaction mixture becomes too high without any reaction control and a large amount of an active intermediate having many reaction active sites is formed, which may cause gelation. As a method for preventing gelation, either a method of controlling generation of silanol groups or a method of directly controlling a gelation reaction of silanol groups generated by hydrolysis is used. These two controlling methods differ in an addition manner of the hydrolyzable silane compound and an amount of water added for hydrolysis.

Of these two methods, the method of controlling generation of silanol groups as described in Japanese Patent Provisional Publication No. 2001-164186 is more typical. In condensation in the presence of an acid catalyst under ordinary conditions, water is added dropwise to the reaction mixture containing a hydrolyzable silane compound. This makes it possible to provide a sufficient time for silanol groups generated by hydrolysis to be consumed for condensation, control a rise in the concentration of the silanol groups and thereby prevent gelation. In addition, gelation is prevented by using a larger amount of an organic solvent having a relatively low polarity while decreasing the total amount of water, thereby avoiding contact between water and the hydrolyzable silane compound and condensing the silanol groups while storing the alkoxy groups without causing an abrupt increase in the concentration of the silanol groups.

In the particular case where no organic solvent is used, an amount of water must be adjusted so as not to exceed 1 mole per 1 mole of a hydrolyzable group in the hydrolyzable silane compound. Even in the typical case where an organic solvent is used, an amount of water is often adjusted similarly so as not to exceed 1 mole per 1 mole of a hydrolyzable group in the hydrolyzable silane compound. Apart from actual use, an upper limit of the amount of water is at most three times or five times larger than the amount necessary for hydrolysis in a patent literature which has a large margin. If the amount of water exceeded 1 mole per 1 mole of a hydrolyzable group in the actual use, there is a risk of gelation. When water is added in an amount of two times the amount necessary for hydrolysis of all hydrolyzable groups as in Comparative Preparation Example which will be described later, a polysiloxane compound cannot be taken out from the reaction mixture due to gelation thereof. In a Preparation Example which will be described later, ²⁹Si—NMR structural analysis of a polysiloxane compound are shown, wherein the polysiloxane compound is synthesized by the above-described silanol group-generation controlling method. The structural analysis indicates that the polysiloxane compound thus obtained is characterized by obvious remaining of alkoxy groups. The results have also revealed that a ratio of silicon units constituting a bond with three or four silicon atoms via oxygen, which is closely related to improvement of the mechanical strength of the polysiloxane compound itself, is relatively low (units indicated by Q4, Q3 and T3 wherein Q is a unit derived from a tetravalent hydrolyzable silane, T is a unit derived from a trivalent hydrolyzable silane, and a numeral is the number of bonds linked to another silicon via oxygen). Particularly a ratio of the unit Q4, which may have a high capacity of providing a rigid structure and thereby improving mechanical strength, is low. Another characteristic is that similarly, a ratio of silicon atoms linked, via oxygen, to one or two silicon atoms which will be a factor for reducing mechanical strength is high. This is because when Si—O—Si bond formation is urged in this method, activity of silanol groups may be beyond control and gelation may occur.

The method of directly controlling a gelation reaction is on the other hand disclosed in Japanese Patent Provisional Publication No. 9-71654. Different from the above-described method, it is characterized by the use of a large excess of water. Active silanol groups are hydrated with a large excess of water, whereby the gelation reaction is controlled. A large amount of an organic solvent which disturbs hydration is not used and more preferably, hydrolysis is performed using a large excess of water without using an organic solvent. In the ordinary reaction operation, the hydrolyzable silane compound is charged in a reaction mixture of hydrolysis so that the reaction mixture constantly contains water in an amount exceeding the molar equivalent of the hydrolyzable groups already charged. It is more common to charge a large excess of water and an acid catalyst in a reaction tank in advance and add the hydrolyzable silane compound dropwise thereto. Such a design enables prompt hydration of silanol groups generated by the hydrolysis.

Although a large amount of silanol groups are generated in the reaction mixture, sufficient hydration always occurs due to existence of a large amount of water and as a result of control of the activity of the silanol groups by hydration, gelation is prevented. An analysis example of the structure of a polysiloxane derivative synthesized by this method is shown in Preparation Example. The polysiloxane derivative available by this method is characterized in that proportions of the above-described units Q4, Q3 and T3 effective for improvement of the mechanical strength are high and proportions of Q2 and T2 which are factors for reducing the strength are low. Another characteristic of this derivative synthesized by this method is that in spite of a high condensation degree, units having silanol groups are not lost while alkoxy groups having a low bond forming activity have almost disappeared at the time of sintering. Moreover, even if a starting substance containing trivalent and tetravalent hydrolyzable silane compounds in an amount exceeding 90% and most likely to cause gelation is used in this method, the polysiloxane derivative can have a molecular weight of 2000 or greater without causing gelation. Such a physical property is also advantageous for fixing the positions of the silicon-oxide-based fine particles.

Japanese Patent Provisional Publication No. 9-71654 discloses that when films different in physical properties due to the difference in structure are formed respectively by the above-described two methods, a polysiloxane derivative synthesized using the latter method in which the silanol activity is prevented by hydration to prevent gelation can provide a film with high hardness. Use of the polysiloxane derivative obtained by the conventional silanol-group-generation controlling method can hardly improve the mechanical strength while maintaining a standard dielectric constant. The polysiloxane derivative obtained by the latter silanol-group-hydrating method is, on the other hand, confirmed to have a function of improving the mechanical strength obviously while maintaining a standard dielectric constant.

In the above-described method, an amount of water used for hydrolysis of the monomer must be sufficient for hydrating the silanol groups generated in the reaction system. The amount of water present in the reaction mixture must always exceed the molar equivalent of the hydrolyzable group of the hydrolyzable silane compound when the compound is added dropwise during the reaction. It is usually convenient to add water to be used for hydrolysis to a reaction tank in advance. As a measure of the amount of water, water is added preferably in an amount of 3 moles or greater, preferably 5 moles or greater, per mole of the hydrolyzable group substituted on all the hydrolyzable silane compounds to be added dropwise. Gelation can usually be prevented almost completely by the addition of water in an amount greater than 5 moles. Described specifically, assuming that the lower limit of the preferred amount of water is 5 moles as described above and the upper limit is 100 moles as described below, each per mole of the hydrolyzable group, when a polysiloxane compound is prepared from the tetravalent hydrolyzable silane compound of the formula (1) and the trivalent compound, among the compounds represented by the formula (2), the following relationship holds:

100×(4×Q+3×T)≧X≧5×(4×Q+3×T)

(wherein Q represents the mole of the compound of the formula (1), T represents the mole of the compound of the formula (2), and X represents the mole of water). By carrying out hydrolysis and condensation reactions in the presence of an acid catalyst while using such a large amount of water, a polysiloxane compound having a high silanol content is available without causing gelation. Addition of water in an amount exceeding 100 moles may be uneconomical because it only enlarges an apparatus used for reactions, though depending on the amount, and raises a cost for drainage treatment.

As the acid catalyst, any known ones are basically usable by properly adjusting the reaction conditions. Use of a catalyst selected from organic sulfonic acids which are said to be strongly acidic among organic acids, and inorganic acids which are said to be more strongly acidic is preferred to allow hydrolysis and condensation reactions to proceed completely. Examples of the inorganic acids include hydrochloric acid, sulfuric acid, nitric acid, and perchloric acid, while those of the organic sulfonic acids include methanesulfonic acid, tosic acid and trifluoromethanesulfonic acid. The amount of the strong acid used as the catalyst is from 10⁻⁶ moles to 1 mole, preferably 10⁻⁵ to 0.5 mole, more preferably 10⁻⁴ to 0.3 mole per mole of the silicon-containing monomer.

A divalent organic acid may be added further in order to heighten the stability of the polysiloxane compound during the reaction. Examples of such an organic acid include oxalic acid, malonic acid, methylmalonic acid, ethylmalonic acid, propylmalonic acid, butylmalonic acid, dimethylmalonic acid, diethylmalonic acid, succinic acid, methylsuccinic acid, glutaric acid, adipic acid, itaconic acid, maleic acid, fumaric acid, and citraconic acid. Of these, oxalic acid and maleic acid are especially preferred. An amount of the organic acid other than the organic sulfonic acid is from 10⁻⁶ moles to 10 moles, preferably 10⁻⁵ to 5 moles, more preferably 10⁻⁴ to 1 mole per mole of the silicon-containing monomer.

The hydrolysis and condensation reactions are started by dissolving the catalyst in water and then adding the monomer to the resulting solution. At this time, an organic solvent may be added to the aqueous solution of the catalyst or the monomer may be diluted in advance with the organic solvent. The reaction temperature is from 0 to 100° C. preferably from 10 to 80° C. It is also preferred to keep the temperature in the range of 10 to 50° C. during dropwise addition of the monomer and then ripen the reaction mixture in the range of 20 to 80° C.

Preferred examples of the organic solvent include methanol, ethanol, 1-propanol, 2-propanol, 1-butanol, 2-butanol, 2-methyl-1-propanol, acetone, acetonitrile, tetrahydrofuran, toluene, hexane, ethyl acetate, cyclohexanone, methyl-2-n-amylketone, propylene glycol monomethyl ether, ethylene glycol monomethyl ether, propylene glycol monoethyl ether, ethylene glycol monoethyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, tert-butyl acetate, tert-butyl propionate, propylene glycol mono-tert-butyl ether acetate, and γ-butyrolactone, and mixtures thereof.

Of these solvents, water soluble ones are preferred. Examples include alcohols such as methanol, ethanol, 1-propanol and 2-propanol; polyols such as ethylene glycol and propylene glycol; polyol condensate derivatives such as propylene glycol monomethyl ether, ethylene glycol monomethyl ether, propylene glycol monoethyl ether, ethylene glycol monoethyl ether, propylene glycol monopropyl ether, and ethylene glycol monopropyl ether; acetone; acetonitrile and tetrahydrofuran.

The organic solvent added in an amount of 50 mass % or greater hinders progress of hydrolysis and condensation reactions so that the amount must be adjusted to less than 50 mass %. Per mole of the monomer, preferably from 0 to 1,000 ml of the organic solvent is added. Use of a large amount of the organic solvent is uneconomical because it requires an unnecessarily large reactor. The amount of the organic solvent is preferably 10 mass % or less based on water. It is most preferred to perform the reactions without the organic solvent.

The hydrolysis and condensation reactions are, if necessary, followed by the neutralization reaction of the catalyst. In order to smoothly conduct the following extraction operation further, the alcohol generated during the hydrolysis and condensation reactions is preferably removed under reduced pressure to obtain an aqueous solution of the reaction mixture. The amount of an alkaline substance necessary for the neutralization is preferably from 1 to 2 equivalents of the inorganic acid or organic sulfonic acid. As the alkaline substance, any substance is usable insofar as it is alkaline in water. Heating temperature of the reaction mixture varies, depending on the kind of the alcohol to be removed, but preferably from 0 to 100° C., more preferably from 10 to 90° C., still more preferably from 15 to 80° C. The degree of vacuum varies, depending on the kind of the alcohol to be removed, exhaust apparatus, condensing apparatus or heating temperature, but is preferably not greater than atmospheric pressure, more preferably an absolute pressure of 80 kPa or less, still more preferably an absolute pressure of 50 kPa or less. It is difficult to know the precise amount of the alcohol to be removed, but about at least 80 mass % of the alcohol generated during the reactions is preferably removed.

In order to remove the catalyst used for the hydrolysis and condensation reactions from the aqueous solution, the polysiloxane compound is extracted with an organic solvent. As the organic solvent, those capable of dissolving therein the polysiloxane derivative and separating a mixture with water into two layers are preferred. Examples include methanol, ethanol, 1-propanol, 2-propanol, 1-butanol, 2-butanol, 2-methyl-1-propanol, acetone, tetrahydrofuran, toluene, hexane, ethyl acetate, cyclohexanone, methyl-2-n-amylketone, propylene glycol monomethyl ether, ethylene glycol monomethyl ether, propylene glycol monoethyl ether, ethylene glycol monoethyl ether, propylene glycol monopropyl ether, ethylene glycol monopropyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, tert-butyl acetate, tert-butyl propionate, propylene glycol mono-tert-butyl ether acetate, γ-butyrolactone, methyl isobutyl ketone and cyclopentyl methyl ether, and mixtures thereof.

Mixtures of a water soluble organic solvent and a sparingly water soluble organic solvent are especially preferred. Preferred examples of the combination include, but not limited to, methanol+ethyl acetate, ethanol+ethyl acetate, 1-propanol+ethyl acetate, 2-propanol+ethyl acetate, propylene glycol monomethyl ether+ethyl acetate, ethylene glycol monomethyl ether+ethyl acetate, propylene glycol monoethyl ether+ethyl acetate, ethylene glycol monoethyl ether+ethyl acetate, propylene glycol monopropyl ether+ethyl acetate, ethylene glycol monopropyl ether+ethyl acetate, methanol+methyl isobutyl ketone, ethanol+methyl isobutyl ketone, 1-propanol+methyl isobutyl ketone, 2-propanol+methyl isobutyl ketone, propylene glycol monomethyl ether+methyl isobutyl ketone, ethylene glycol monomethyl ether+methyl isobutyl ketone, propylene glycol monoethyl ether+methyl isobutyl ketone, ethylene glycol monoethyl ether+methyl isobutyl ketone, propylene glycol monopropyl ether+methyl isobutyl ketone, ethylene glycol monopropyl ether+methyl isobutyl ketone, methanol+cyclopentyl methyl ether, ethanol+cyclopentyl methyl ether, 1-propanol+cyclopentyl methyl ether, 2-propanol+cyclopentyl methyl ether, propylene glycol monomethyl ether+cyclopentyl methyl ether, ethylene glycol monomethyl ether+cyclopentyl methyl ether, propylene glycol monoethyl ether+cyclopentyl methyl ether, ethylene glycol monoethyl ether+cyclopentyl methyl ether, propylene glycol monopropyl ether+cyclopentyl methyl ether, ethylene glycol monopropyl ether+cyclopentyl methyl ether, methanol+propylene glycol methyl ether acetate, ethanol+propylene glycol methyl ether acetate, 1-propanol+propylene glycol methyl ether acetate, 2-propanol+propylene glycol methyl ether acetate, propylene glycol monomethyl ether+propylene glycol methyl ether acetate, ethylene glycol monomethyl ether+propylene glycol methyl ether acetate, propylene glycol monoethyl ether+propylene glycol methyl ether acetate, ethylene glycol monoethyl ether+propylene glycol methyl ether acetate, propylene glycol monopropyl ether+propylene glycol methyl ether acetate, and ethylene glycol monopropyl ether+propylene glycol methyl ether acetate.

The mixing ratio of the water soluble organic solvent and the hardly-water-soluble organic solvent is determined as needed, but the water soluble organic solvent is added in an amount of from 0.1 to 1000 parts by mass, preferably from 1 to 500 parts by mass, more preferably from 2 to 100 parts by mass, based on 100 parts by mass of the hardly-water-soluble organic solvent.

The organic layer obtained after the removal of the catalyst used for the hydrolysis and condensation reactions is mixed in a porous-film-forming composition after partial distillation of the solvent under reduced pressure and solvent substitution by re-dilution.

An undesirable impurity which is thought to be a microgel is sometimes mixed in the reaction mixture due to fluctuations in the conditions during the hydrolysis reaction or concentration. The microgel can be removed by washing with water prior to mixing of the polysiloxane compound as a composition. When washing with water is not so effective for the removal of the microgel, this problem may be overcome by washing the polysiloxane compound with acidic water and subsequently with water.

The acidic water usable for the above purpose contains preferably a divalent organic acid, more specifically, oxalic acid or maleic acid. The concentration of the acid contained in the acidic water is preferably from 100 ppm to 25 mass %, more preferably from 200 ppm to 15 mass %, still more preferably from 500 ppm to 5 mass %. The amount of the acidic water is from 0.01 to 100 L, preferably from 0.05 to 50 L, more preferably from 0.1 to 5 L per 1 L of the polysiloxane compound solution obtained in the above-described step. The organic layer may be washed in a conventional manner. Both of them are charged in the same container, stirred, and left to stand to separate a water layer from the mixture. The washing may be performed at least once. Washing ten times or more is fruitless so that the washing is performed preferably from once to about five times.

The acid used for washing is then removed by washing with neutral water. It is only necessary to use, for this washing, water called deionized water or ultrapure water. The neutral water is used preferably in an amount of from 0.01 to 100 L, more preferably from 0.05 to 50 L, still more preferably from 0.1 to 5 L per 1 L of the polysiloxane compound solution washed with the acidic water. The washing is performed in the above-described manner, more specifically, by charging them in the same container, stirring the resulting mixture and leaving it to stand to separate a water layer from the mixture. The washing may be performed at least once. Washing ten times or more is fruitless so that the washing is performed preferably from once to about five times.

To the polysiloxane compound solution which has finished washing, a solvent for preparing a coating composition, which will be described later, is added. By performing a solvent exchange under reduced pressure, a mother solution to be added to the porous-film-forming composition can be obtained. This solvent exchange may be carried out after addition of silicon oxide fine particles which will be described later. The solvent exchange is conducted at a temperature which varies, depending on the kind of the extraction solvent to be removed, but is preferably from 0 to 100° C., more preferably from 10 to 90° C., still more preferably from 15 to 80° C. The degree of vacuum varies depending on the kind of the extraction solvent to be removed, exhaust gas apparatus, condensing apparatus or heating temperature, but is preferably not greater than the atmospheric pressure, more preferably an absolute pressure of 80 kPa or less, still more preferably an absolute pressure of 50 kPa or less.

When the solvent is exchanged, nanogel may be generated due to loss of stability of the polysiloxane compound. The generation of the nanogel depends on the affinity between the final solvent and polysiloxane compound. An organic acid may be added to prevent the generation of it. As the organic acid, divalent ones such as oxalic acid and maleic acid, and monovalent carboxylic acids such as formic acid, acetic acid and propionic acid are preferred. The amount of the organic acid is preferably from 0 to 25 mass %, more preferably from 0 to 15 mass %, still more preferably from 0 to 5 mass % based on the polymer in the solution before the solvent exchange. When the organic acid is added, its amount is preferably 0.5 mass % or greater. If necessary, the acid may be added to the solution before the solvent exchange step and then, the solvent exchange operation may be performed.

As described above, the polysiloxane compound obtained in the above-described method can have, in the molecule thereof, a greater amount of silanol groups compared with that obtained by the conventional method using hydrolysis and condensation reactions. Described specifically, the polysiloxane compound is composed of units (Q1 to Q4, T1 to T3) represented by the following formulas:

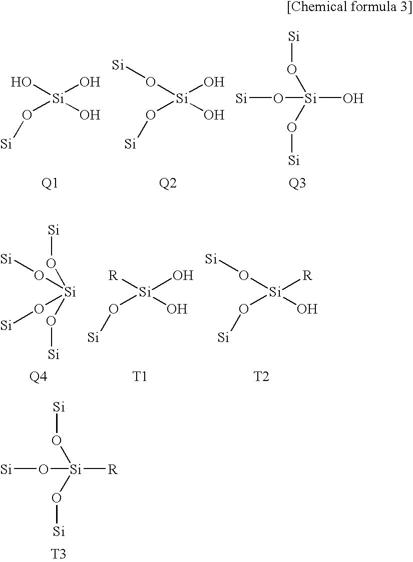

(wherein, Q means a unit derived from a tetravalent hydrolyzable silane, T means a unit derived from a trivalent hydrolyzable silane, and R in T1 to T3 indicates that a bond represented by Si—R is a bond between silicon and a carbon substituent). By the above-described method, the polysiloxane compound satisfying the following relationships are available supposing that the molar ratio of each unit determined by ²⁹Si—NMR is q1, q2, q3, q4, t1, t2, and t3, respectively:

(q1+q2+t1)/(q1+q2+q3+q4+t1+t2+t3)≦0.2 and

(q3+t2)/(q1+q2+q3+q4+t1+t2t3)≧0.4.

Use of the polysiloxane compound satisfying the above-described ranges enables improvement of the function of the porous-film-forming composition of the invention further.

The silicon-oxide-based fine particles, another main component of the porous-film-forming composition of the invention, will hereinafter be described.

In the porous-film-forming composition of the invention, the mechanical strength of the whole film is improved by strongly bonding silicon-oxide-based fine particles, which is an important factor for maintaining mechanical strength of a thin film obtained by the coating method, during film formation by utilizing the polysiloxane compound having a high concentration of silanol groups. Any silicon-oxide-based fine particles which have been used for conventional porous-film-forming compositions can be employed. Examples of the conventionally used silicon-oxide-based fine particles include zeolite fine particles which are expected to exhibit high mechanical strength but are prepared in a very cumbersome manner and silica fine particles which can be easily prepared.

With regards to zeolite fine particles usable as silicon-oxide-based fine particles of the porous-film-forming composition of the invention, many methods for applying zeolite fine particles to a porous-film-forming composition are known (for example, Japanese Patent Provisional Publication Nos. 2004-161535 and 2005-216895) and any of them is applicable to them. The term “zeolite” often means a material having silicon and oxygen atoms arranged with long-distance regularity but the term herein means a material having silicon and oxygen atoms arranged with regularity like the crystal structure of zeolite and including zeolite seed crystals having a particle size of about several mm.

In the crystal structure of zeolite, there are a number of pores having a pore size of from about 0.4 to 0.8 nm. Such a structure provides micro-pores and in addition, due to its crystal structure, it has very high mechanical strength. Zeolite fine particles are therefore advantageous as a material for forming a porous film with high mechanical strength.

Zeolite fine particles can be obtained preferably by hydrolysis and condensation reactions while using a combination of a tetraalkoxysilane and a specified basic substance, especially a quaternary ammonium hydroxide. For example, a suspension of zeolite fine particles can be prepared by adding tetrapropylammonium hydroxide (from 20 to 25 mass %) to tetraethylorthosilicate and ripening at 30° C. for 3 days and then at 80° C. for 25 hours.

For preparation of such zeolite fine particles, at least one silane compound represented by the following formula (8):

Si(OR⁸)₄ (8)

(wherein, R⁸s may be the same or different and each independently represents a linear or branched C₁₋₄ alkyl group which may have a substituent) can be used as a raw material. Examples of the silane compound include tetramethoxysilane, tetraethoxysialne, tetrapropoxysilane and tetrabutoxysilane.

As a catalyst for hydrolysis, quaternary ammonium hydroxides represented by the following formula (9):

(R⁹)₄N⁺OH⁻ (9)

(wherein, R⁹s may be the same or different and each independently represents a linear, branched or cyclic C₁₋₂₀ alkyl group) can be used, for example. Specific examples of the quaternary ammonium hydroxide of the formula (9) include tetramethylammonium hydroxide, tetraethylammonium hydroxide, tetrapropylammonium hydroxide, tetrabutylammonium hydroxide and choline, with tetrapropylammonium hydroxide being especially preferred.

The quaternary ammonium hydroxide is added as a catalyst in an amount of preferably from 0.001 to 50 moles, more preferably form 0.01 to 5.0 moles per mole of the silane compound. For hydrolysis, water is used in an amount necessary for completely hydrolyzing the silane compound. Its amount is preferably from 0.5 to 100 moles, more preferably from 1 to 10 moles per mole of the silane compound.

When zeolite fine particles are prepared by hydrolysis of the silane compound, a solvent such as alcohol corresponding to the alkoxy group of the silane compound can be added as well as water. Examples of the solvent include methanol, ethanol, isopropyl alcohol and butanol.

The amount of the solvent other than water is preferably from 0.1 to 10 times, more preferably from 0.5 to 2 times the mass of the silane compound.

The hydrolysis time of the silane compound represented by the formula (8) is preferably from 1 to 100 hours, more preferably from 10 to 70 hours and hydrolysis temperature is preferably from 0 to 50° C., more preferably from 15 to 30° C.

Heat treatment after hydrolysis is performed preferably at 30° C. or greater, more preferably 50° C. or greater. When the temperature exceeds the boiling point of the solvent used for hydrolysis at an atmospheric pressure, the heat treatment may be performed in a hermetically sealed container. When the temperature exceeds 85° C., however, mixing of a large amount of particles having a particle size exceeding 100 nm occurs so that the temperature is preferably adjusted to 85° C. or less.

The heat treatment time is preferably from 1 to 100 hours, more preferably from 10 to 70 hours.

The zeolite fine particles obtained in the above-described manner can be used as are as silicon-oxide-based fine particles to be added to the composition, but in order to raise the crosslink formation activity during sintering, zeolite fine particles subjected to crosslinkable-side-chain modification treatment with a hydrolyzable silane as described below can be used.

The crosslinkable-side-chain modification treatment with a hydrolyzable silane can be conducted by the dropwise addition, to zeolite fine particles, of at least one hydrolyzable silane selected from the group consisting of compounds represented by the following formulas (10) and (11):

Si(OR¹⁰)₄ (10)

R¹¹_{q}Si(OR¹²)_{4-q} (11)

(wherein, R¹⁰s may be the same or different and each independently represents a linear or branched C₁₋₄ alkyl group, R¹¹(s) may be the same or different when there are plural R¹¹s and each independently represents a linear or branched C₁₋₈ alkyl group, R¹²(s) may be the same or different when there are plural R¹²s and each independently represents a linear or branched C₁₋₄ alkyl group, and q is an integer from 1 to 3) in the presence of an alkaline catalyst at the temperature from 15 to 80° C. Ripening for several hours or more is not particularly required.

In order to leave the crosslink formation activity after modification, it is preferred to add a divalent or polyvalent carboxylic acid compound in the early stage after completion of the reaction so as to protect active silanol. It is added preferably within 2 hours, especially preferably just after completion of the reaction in order to prevent deterioration of its effect with the passage of time.

The term “divalent or polyvalent carboxylic acid compound” as used herein means a compound having or capable of forming, in the molecule thereof, at least two carboxyl groups or derivatives thereof. Examples of the divalent carboxylic acid include oxalic acid, malonic acid, malonic anhydride, maleic acid, maleic anhydride, fumaric acid, glutaric acid, glutaric anhydride, citraconic acid, citraconic anhydride, itaconic acid, itaconic anhydride and adipic acid.

The divalent or polyvalent carboxylic acid compound is added preferably in an amount of from 0.005 to 0.5 mole relative to the alkoxy group and/or silanol group of the hydrolyzable silane compound used for modification.

The zeolite fine particles or silicon-oxide-based fine particles containing zeolite thus prepared can be added with a solvent immiscible with water and then washed with water for the purpose of removing unnecessary salts contained in the solution or traces of metals which may be contained in the solution. Examples of the solvent to be used for this purpose include pentane, hexane, benzene, toluene, methyl ethyl ketone, methyl isobutyl ketone, 1-butanol, ethyl acetate, butyl acetate and isobutyl acetate.

Similar to the above-described polysiloxane compound prepared from a large amount of water and acid catalyst, the zeolite fine particles or zeolite-containing silicon-oxide-based fine particles thus prepared are preferably converted into the form of a solution in a solvent suited for application and provided finally as a mother solution for preparing a coating composition. Examples of the solvent usable for such a purpose include aliphatic hydrocarbon solvents such as n-pentane, isopentane, n-hexane, isohexane, n-heptane, 2,2,2-trimethylpentane, n-octane, isooctane, cyclohexane and methylcyclohexane; aromatic hydrocarbon solvents such as benzene, toluene, xylene, ethylbenzene, trimethylbenzene, methylethylbenzene, n-propylbenzene, isopropylbenzene, diethylbenzene, isobutylbenzene, triethylbenzene, diisopropylbenzene and n-amylnaphthalene; ketone solvents such as acetone, methyl ethyl ketone, methyl n-propyl ketone, methyl n-butyl ketone, methyl isobutyl ketone, cyclohexanone, 2-hexanone, methylcyclohexanone, 2,4-pentanedione, acetonylacetone, diacetone alcohol, acetophenone, and fenthion; ether solvents such as ethyl ether, isopropyl ether, n-butyl ether, n-hexyl ether, 2-ethylhexyl ether, dioxolane, 4-methyldioxolane, dioxane, dimethyldioxane, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol dimethyl ether, diethylene glycol monoethyl ether, diethylene glycol diethyl ether, diethylene glycol monopropyl ether, diethylene glycol dipropyl ether, diethylene glycol monobutyl ether, diethylene glycol dibutyl ether, tetrahydrofuran, 2-methyltetrahydrofuran, propylene glycol monomethyl ether, propylene glycol dimethyl ether, propylene glycol monoethyl ether, propylene glycol diethyl ether, propylene glycol monopropyl ether, propylene glycol dipropyl ether, propylene glycol monobutyl ether, dipropylene glycol dimethyl ether, dipropylene glycol diethyl ether, dipropylene glycol dipropyl ether and dipropylene glycol dibutyl ether, ester solvents such as diethyl carbonate, ethyl acetate, γ-butyrolactone, γ-valerolactone, n-propyl acetate, isopropyl acetate, n-butyl acetate, isobutyl acetate, sec-butyl acetate, n-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, dipropylene glycol monomethyl ether acetate, dipropylene glycol monoethyl ether acetate, dipropylene glycol mono-n-butyl ether acetate, glycol diacetate, methoxytriglycol acetate, ethyl propionate, n-butyl propionate, isoamyl propionate, diethyl oxalate, di-n-butyl oxalate, methyl lactate, ethyl lactate, n-butyl lactate, n-amyl lactate, diethyl malonate, dimethyl phthalate and diethyl phthalate; nitrogen-containing solvents such as N-methylformamide, N,N-dimethylformamide, acetamide, N-methylacetamide, N,N-dimethylacetamide, N-methylpropionamide, and N-methylpyrrolidone, and sulfur-containing solvents such as dimethyl sulfide, diethyl sulfide, thiophene, tetrahydrothiophene, dimethyl sulfoxide, sulfolane, and 1,3-propanesultone. These solvents may be used either singly or in combination.

The silica fine particles as the other preferred silicon-oxide-based fine particles to be used in the invention are particularly excellent in industrial availability. Many silica fine particles are disclosed in, for example, Japanese Patent Provisional Publication Nos. 315812/1997 or 2004-165402. Although any of them is usable, those having high strength are particularly effective in the method of the invention. The preferred silica fine particles will next be described.

A typical example of the silica fine particles preferably used for the porous-film-forming composition of the invention is a silica sol obtained by hydrolysis and condensation reactions, in the presence of an alkaline catalyst, of a hydrolyzable silane compound containing at least one tetrafunctional alkoxysilane compound represented by the following formula (3):

Si(OR⁴)₄ (3)

(wherein, R⁴s may be the same or different and each independently represents a linear or branched C₁₋₄ alkyl group) and at least one alkoxysilane compound represented by the following formula (4):

R⁵ₘSi(OR⁶)₄₋ₘ (4)

(wherein, R⁵(s) may be the same or different when there are plural R⁵s and each independently represents a linear or branched C₁₋₈ alkyl group, R⁶(s) may be the same or different when there are plural R⁶s and each independently represents a linear or branched C₁₋₄ alkyl group, and m is an integer from 1 to 3).

A proportion of the compound of the formula (3) is, in terms of silicon atoms, preferably 10 mole % or greater but not greater than 90 mole %, more preferably 30 mole % or greater but not greater than 70 mole %, each based on the total moles of the hydrolyzable silane compound used for hydrolysis and condensation reactions in the presence of an alkaline catalyst, that is, the total moles of the compounds (3) and (4).

Preferred examples of R⁵ of the alkoxysilane compound (4) include alkyl groups such as methyl, ethyl, n-propyl, iso-propyl, n-butyl, iso-butyl, sec-butyl, t-butyl, n-pentyl, 2-ethylbutyl, 3-ethylbutyl, 2,2-diethylpropyl, cyclopentyl, n-hexyl and cyclohexyl; alkenyl groups such as vinyl and allyl; alkynyl groups such as ethynyl; aryl groups such as phenyl and tolyl; aralkyl groups such as benzyl and phenethyl, and other unsubstituted monovalent hydrocarbon groups. They may each have a substituent such as fluorine.

Examples of the silane compound (3) include, but not limited to, methyltrimethoxysilane, methyltriethoxysilane, methyltripropoxysilane, methyltriisopropoxysilane, ethyltrimethoxysilane, ethyltriethoxysilane, ethyltripropoxysilane, propyltrimethoxysilane, propyltriethoxysilane, isopropyltrimethoxysilane, isopropyltriethoxysilane, butyltrimethoxysilane, butyltriethoxysilane, pentyltrimethoxysilane, pentyltriethoxysilane, hexyltrimethoxysilane, cyclohexyltrimethoxysilane and octyltrimethoxysilane; while those of the compound (4) include, but not limited to, tetramethoxysilane, tetraethoxysilane, tetrapropoxysilane and tetraisopropoxysilane.

The above-described silane compounds are preferred examples as a main component, but another silane may be added as an auxiliary component. Examples of such a silane include dimethyldimethoxysilane, dimethyldiethoxysilane, hexamethyldisiloxane, methylenebistrimethoxysilane, methylenebistriethoxysilane, 1,3-propylenebistrimethoxysilane, 1,4-bistrimethoxysilane and 1,4-phenyylenebistrimethoxysilane. These hydrolyzable silanes other than those of the formulas (3) and (4) are added preferably in an amount of 30 mole % or less, in terms of silicon atoms, based on the total amount of all the hydrolyzable silane compounds to be used for the reaction.

It is described in Japanese Patent Provisional Publication No. 2001-164186 that the above-described hydrolyzable silane compounds sometimes cannot be converted into fine particles under some conditions even in the presence of a basic catalyst, but they are available as fine particles under the following conditions.

Examples of basic catalysts include amines such as ammonia, methylamine, dimethylamine, trimethylamine, ethylamine, diethylamine, triethylamine, propylamine, dipropylamine, tripropylamine, diisobutylamine, butylamine, dibutylamine, tributylamine, triethanolamine, pyrrolidine, piperidine, morpholine, piperazine, pyridine, pyridazine, pyrimidine, pyrazine and triazine; quaternary ammonium hydroxides such as tetramethylammonium hydroxide, tetraethylammonium hydroxide, tetrapropylammonium hydroxide, tetrabutylammonium hydroxide and choline; and hydroxides of an alkali metal or alkaline earth metal such as sodium hydroxide, potassium hydroxide and calcium hydroxide. Of these, the strong basic catalysts such as quaternary ammonium hydroxides and alkali metal hydroxides can provide a silica sol having a higher particle property.

Moreover, of the above-described strong basic catalysts, bases selected from alkali metal hydroxides and hydrophilic quaternary ammonium hydroxides, such as tetrabutylammonium hydroxide and choline, represented by the following formula (5):

(R⁷)₄N⁺OH⁻ (5)

(wherein, the cationic portion [(R⁷)₄N⁺] satisfies the following relationship (6):

(N+O)/N+O+C)≧⅕ (6)

in which, N, O and C are the numbers of nitrogen, oxygen and carbon atoms contained in the cationic portion, respectively) are preferred as a catalyst for obtaining silica fine particles to be used in the composition of the invention, because they can provide hard silica fine particles which are presumed to have a high crosslinking density.

R⁷ represents an organic group composed of carbon, hydrogen and oxygen and examples of such a group include C₁₋₂₀ alkyl groups which may have a hydroxyl group or may have a —O—, —(C═O)— or —(C═O)O— structure therein.

Moreover, use, for a porous-film-forming composition, of silica fine particles obtained in the presence of at least one base selected from the hydrophilic quaternary ammonium hydroxides and metal hydroxides, and a hydrophobic quaternary ammonium hydroxide not satisfying the above relationship (6) used in combination as a catalyst enables preparation of a porous film having higher mechanical strength. The present inventors think the reason of it as follows. When a hydrophobic basic catalyst and a hydrophilic base catalyst are used in combination, an association state is formed through the hydrophobic interaction between the hydrophobic basic catalyst and alkoxysilane. The association state may be maintained even after the partial progress of hydrolysis of the alkoxysilane into silanol by the static interaction between silanol (silicate) and ammonium cation. The hydrophilic catalyst then may act to promote the condensation reaction of silanol and may form a firm siloxane bond at a high reactivity. Another associate between the hydrophobic basic catalyst and alkoxysilane may act to form an association state with a silica surface, followed by promotion of the condensation reaction by the hydrophilic basic catalyst. Repetition of such reactions may lead to the growth of a silica sol. In a film obtained using the silica sol thus obtained in the above manner, almost no micropores are observed so that it is not a silica sol partially having a zeolite-like crystal structure. Due to the combined use with the hydrophilic basic catalyst, the growth of the silica sol may proceed according to the above-described mechanism in which a large amount of the hydrophobic basic catalyst does not remain in the silica sol. Such mechanism may enable to form amorphous silica with less internal strains and a high crosslinking ratio instead of forming a crystal such as a zeolite structure. Moreover, silica gel obtained as a result of the condensation reaction, in which an internal strain is sufficiently relaxed, may have a small amount of silanol residue therein and thus may be rigid and highly hydrophobic. When a low dielectric constant film is formed as described later, the film may therefore have high strength and stable dielectric constant.

For synthesizing silica fine particles which can be added as silicon-oxide-based fine particles to the porous-film-forming composition of the invention, use of a silsesquioxane cage compound represented by the following formula (7):

(SiO_{1.5}—O)ₚ^{p-}(X⁺)ₚ (7)

(wherein X represents NR¹³₄, R¹³ may be the same or different and each independently represents a linear or branched C₁₋₄ alkyl group and p is an integer from 6 to 24) and prepared in advance as at least a portion of the alkaline catalyst is preferred.

As the silsesquioxane cage compound, those from hexamer to dodecamer are known to have a relatively stable structure from the thermodynamical viewpoint and existence of those up to octadecamer is confirmed (P. A. Agskar, W. Klemperer., Inorg. Chim. Acta, 299, 355 (1995)). Of these, the octamer is typical.

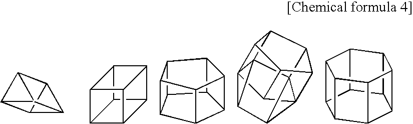

(wherein a silicon atom is located at each vertex and each side represents an Si—O—Si bond).

The silicon atom at each vertex of the above-described structures has one more remaining bonding site. When the remaining bonding site has a hydroxyl group as a substituent, it is acidic as silanol. A salts formed by this acidic hydroxyl group with a quaternary ammonium is the salt of a silsesquioxane cage compound. The octamer, a typical example, is a compound represented by the following formula:

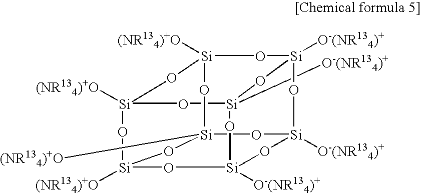

(wherein X represents NR¹³₄ and R¹³s may be the same or different and each independently represents a linear or branched C₁₋₄ alkyl group).

It is known that a tetraalkylammonium salt of the silsesquioxane cage compound (octamer) can be synthesized by reacting powders of silica such as tetraalkoxysilane or Aerosil (trade name) with a tetraalkylammonium hydroxide in a water-containing solvent. This method is described, for example, in E. Muller, F. T. Edelmann, Main Group Metal Chemistry, 22, 485 (1999) or M. Moran, et al., Organometallics, 4327 (1993). A tetramethylammonium salt (60 hydrate) of the octamer is commercially available, for example, from Hybrid Plastics Inc.

When the above-described method is employed, the hydrolyzable silane compound (3) and/or (4) is added to the salt of a cage compound prepared in advance to cause a reaction between them. Due to the interaction with an atom to be bound to a silicon atom and action of the coordinated quaternary ammonium cation, the salt of a cage compound is condensed with the hydrolyzed silane monomer at a condensation speed higher than that between other monomers. Similarly, the condensate resulting from the condensation is also condensed with the hydrolyzed silane monomer at a condensation speed higher than that between other monomers. This means that the salt of a silsesquioxane cage compound serves not only as an alkaline catalyst but also as a nucleus for the growth of silica fine particles, whereby silica fine particles with high strength can be obtained.

In order to accelerate the hydrolysis of the hydrolyzable silane for promoting growth of the silica fine particles, another basic catalyst may be used in combination with said salt of the silsesquioxane cage compound. Any of the above-described conventional basic catalysts may be used for this purpose. When an excess of a strongly basic metal hydroxide or quaternary ammonium hydroxide having high condensation activity is added, however, a large amount of condensates between monomers are produced and there is a possibility of it impairing the advantage of the use of the salt of a silsesquioxane cage compound. When the basic metal hydroxide or quaternary ammonium hydroxide having high condensation activity is used, therefore, the amount thereof is suppressed to preferably 100 times the mole or less, more preferably 30 times the mole or less of the salt of a silsesquioxane cage compound.

In any case including the above-described special case, the amount of the basic catalyst is within a range of from 0.001 to 10 times the mole, preferably from 0.01 to 1.0 time the mole of the silane compound. The amount of water used for hydrolysis is preferably from 0.5 to 100 times, more preferably from 1 to 10 times the moles necessary for complete hydrolysis of the silane compound.

The hydrolysis and condensation reactions for hydrolyzing the silane compound to prepare fine particles are performed in the presence of water. A solvent can also be used as well as water. Examples include methanol, ethanol, isopropyl alcohol, butanol, propylene glycol monomethyl ether, and propylene glycol monopropyl ether. Additional examples include acetone, methyl ethyl ketone, tetrahydrofuran, acetonitrile, formamide, dimethylformamide, dimethylacetamide and dimethylsulfoxide. The amount of the solvent other than water is preferably from 1 to 1000 times the mass, more preferably from 2 to 100 times the mass of the silane compound.

Hydrolysis and condensation reactions of the silane compound are conducted for preferably from 0.01 to 100 hours, more preferably from 0.1 to 50 hours and at preferably from 0 to 100° C., more preferably from 10 to 80° C. Under the above-described conditions, silica is typically obtained in the form of particles because the hydrolyzable silane compound forms bonds faster with silicon atoms forming many bonds to silicon atoms via oxygen atoms than with silicon atoms forming many bonds to carbon atoms via oxygen atoms. In order to improve the particle property of the silica, it is preferred to add the hydrolyzable silica compound dropwise to the reaction mixture under the reaction conditions.

For termination of the reaction and post treatment, any known method is basically usable. The method (Japanese Patent Provisional Publication No. 2005-216895) for storing the crosslink formation activity of silica fine particles, thereby improving the mechanical strength of a film available after sintering is also effective in combined use with the invention. Described specifically, it is preferred to protect the active silanol by adding a divalent or polyvalent carboxylic acid compound after the neutralization reaction of the basic catalyst but prior to loss of the crosslink activity, more preferably, just after the neutralization reaction of the basic catalyst. It is more preferred to effect the neutralization reaction itself with a divalent or polyvalent carboxylic acid so as to simultaneously carry out neutralization and silanol protection and cap the crosslinkable sites until completion of the decomposition of the carboxylic acid compound during film formation.

Preferred examples of the carboxylic acid having, in the molecule thereof at least two carboxyl groups include oxalic acid, malonic acid, malonic anhydride, maleic acid, maleic anhydride, fumaric acid, glutaric acid, glutaric anhydride, citraconic acid, citraconic anhydride, itaconic acid, itaconic anhydride and adipic acid. Such a carboxylic acid acts effectively when added in an amount ranging from 0.05 mole % to 10 mole %, preferably from 0.5 mole % to 5 mole % based on the silicon unit.

The solution of polysiloxane fine particle thus prepared may be added with a water immiscible solvent and then washed with water for the purpose of removing unnecessary salts contained in the solution or traces of metals which may be mixed in the solution. Examples of the solvent to be used for this purpose include pentane, hexane, benzene, toluene, methyl ethyl ketone, methyl isobutyl ketone, 1-butanol, ethyl acetate, butyl acetate and isobutyl acetate.

The polysiloxane compound thus prepared is, similar to the above-described polysiloxane compound prepared using a large amount of water and acid catalyst, preferably converted into the form of a solution in a solvent suited for application and provided as a mother solution for preparing a coating solution. Examples of the solvent used for such a purpose include aliphatic hydrocarbon solvents such as n-pentane, isopentane, n-hexane, isohexane, n-heptane, 2,2,2-trimethylpentane, n-octane, isooctane, cyclohexane and methylcyclohexane; aromatic hydrocarbon solvents such as benzene, toluene, xylene, ethylbenzene, trimethylbenzene, methylethylbenzene, n-propylbenzene, isopropylbenzene, diethylbenzene, isobutylbenzene, triethylbenzene, diisopropylbenzene and n-amylnaphthalene; ketone solvents such as acetone, methyl ethyl ketone, methyl n-propyl ketone, methyl n-butyl ketone, methyl isobutyl ketone, cyclohexanone, 2-hexanone, methylcyclohexanone, 2,4-pentanedione, acetonylacetone, diacetone alcohol, acetophenone, and fenthion; ether solvents such as ethyl ether, isopropyl ether, n-butyl ether, n-hexyl ether, 2-ethylhexyl ether, dioxolane, 4-methyldioxolane, dioxane, dimethyldioxane, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol dimethyl ether, diethylene glycol monoethyl ether, diethylene glycol diethyl ether, diethylene glycol monopropyl ether, diethylene glycol dipropyl ether, diethylene glycol monobutyl ether, diethylene glycol dibutyl ether, tetrahydrofuran, 2-methyltetrahydrofuran, propylene glycol monomethyl ether, propylene glycol dimethyl ether, propylene glycol monoethyl ether, propylene glycol diethyl ether, propylene glycol monopropyl ether, propylene glycol dipropyl ether, propylene glycol monobutyl ether, dipropylene glycol dimethyl ether, dipropylene glycol diethyl ether, dipropylene glycol dipropyl ether and dipropylene glycol dibutyl ether, ester solvents such as diethyl carbonate, ethyl acetate, γ-butyrolactone, γ-valerolactone, n-propyl acetate, isopropyl acetate, n-butyl acetate, isobutyl acetate, sec-butyl acetate, n-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, dipropylene glycol monomethyl ether acetate, dipropylene glycol monoethyl ether acetate, dipropylene glycol mono-n-butyl ether acetate, glycol diacetate, methoxytriglycol acetate, ethyl propionate, n-butyl propionate, isoamyl propionate, diethyl oxalate, di-n-butyl oxalate, methyl lactate, ethyl lactate, n-butyl lactate, n-amyl lactate, diethyl malonate, dimethyl phthalate and diethyl phthalate; nitrogen-containing solvents such as N-methylformamide, N,N-dimethylformamide, acetamide, N-methylacetamide, N,N-dimethylacetamide, N-methylpropionamide, and N-methylpyrrolidone, and sulfur-containing solvents such as dimethyl sulfide, diethyl sulfide, thiophene, tetrahydrothiophene, dimethyl sulfoxide, sulfolane, and 1,3-propanesultone. These solvents may be used either singly or in combination.

A porous-film-forming composition is prepared by the steps of:

mixing a solution of the polysiloxane compound prepared using a large amount of water and acid catalyst with a solution of the silicon-oxide-based fine particles such as zeolite derivative, or polysiloxane fine particles obtained in the presence of the alkaline catalyst;

adding, if necessary, auxiliary components such as surfactant; and

finally adjusting the concentration of the mixture. When an amount of the polysiloxane compound prepared using a large amount of water and acid catalyst is too small, it cannot bring about effects for improving mechanical strength, while when it is too large, the dielectric constant cannot be suppressed to low levels. The amount of the polysiloxane compound is preferably from 1 to 40 mass %, more preferably from 1 to 20 mass % based on the amount of the silicon-oxide-based fine particles.

Degree of dilution for final adjustment of the concentration differs, depending on the viscosity or target film thickness, but dilution is typically performed to give a solvent amount of from 50 to 99 mass %, more preferably from 75 to 95 mass %.

After preparation of the porous-film-forming composition in the above-described manner, the composition is spin coated onto a target substrate at an adequate rotation speed while controlling the solute concentration of the composition, whereby a thin film having a desired thickness can be formed.

A thin film having a thickness of about 0.1 to 1.0 μm thick is typically formed in practice, but the film thickness is not limited thereto. A thin film with a greater thickness can be formed by carrying out coating of the composition plural times.

Not only spin coating but also the other coating method such as scan coating can be employed.

The thin film thus formed can be converted into a porous film in a known manner. Described specifically, the porous film is available as a final product by removing the solvent from the thin film by using an oven in a drying step (typically called pre-bake step in a semiconductor fabrication process) to heat it to preferably from 50 to 150° C. for several minutes and then sintering it at 350° C. to 450° C. for about 5 minutes to 2 hours. A curing step with ultraviolet radiation, electron beam or the like may be added further.

The porous film of the invention has high mechanical strength compared with that obtained using a conventional composition, wherein the porous film is obtained by the porous-film-forming composition having the polysiloxane compound prepared using a large amount of water and acid catalyst, and the silicon-oxide-based fine particles, especially zeolite derivative or polysiloxane fine particles obtained using the alkaline catalyst. The present inventors think the reason for its high mechanical strength as follows.

If a material used for forming a film were made of completely uniform particles and a uniform force acts between any two particles, the mechanical strength of the film would depend on the network skeleton formed by the particles. When a film is designed to have a low dielectric constant, in other words, have an increased porosity, a proportion of the network skeleton present in a certain space decreases, leading to a reduction in mechanical strength. There is a trade-off relationship between a reduction in dielectric constant and an increase in mechanical strength. In fact, when polysiloxane fine particles prepared under varied reaction conditions are used for the composition, the dielectric constant and mechanical strength of the film obtained using the composition change simultaneously. An almost linear relationship is observed between them particularly in a range of a dielectric constant from 2.0 to 3.0. In the invention, when the polysiloxane compound prepared using a large amount of water and acid catalyst is added, on the other hand, the mechanical strength becomes higher at the same dielectric constant, than that predicted by the above-described linear relationship when only a specific zeolite derivative or polysiloxane fine particles are added. This occurs because the polysiloxane compound, which is prepared using a large amount of water and acid catalyst, is rich in silanol groups having a high crosslinking performance so that crosslinks can be formed easily between the fine particle and the polysiloxane compound. As a result the crosslinks reinforce the bonds between the fine particles. In short, since no significant difference exists in the skeleton formed by fine particles between the above-described model and a film obtained by the conventional method, an increase in force acting between fine particles leads to higher mechanical strength even if there occurs no change in a dielectric constant due to porosity.

A low-dielectric-constant porous film to be used for semiconductor devices has conventionally a problem of deterioration in the mechanical strength of the film because introduction of pores into the film for reducing its dielectric constant and making the film porous decreases the density of the material constituting the film. The deterioration in the mechanical strength not only has an influence on the strength of semiconductor devices themselves but also causes peeling of the film due to lack of sufficient strength against chemical mechanical polishing typically employed for the semiconductor fabrication process.

A porous film obtained by coating the porous-film-forming composition of the invention on a substrate and then sintering can have both a low dielectric constant and high mechanical strength simultaneously. In particular, when the porous film is used as an interlayer insulating film of semiconductor devices, it does not cause such peeling and enables fabrication of highly-reliable, high-speed and small-sized semiconductor devices because it has high mechanical strength and low dielectric constant in spite of its poromeric structure.

A semiconductor device containing the porous film is also one of the inventions. The term “interlayer insulating film” as used herein may mean a film for electrically insulating conductive sites present in a layer or a film for electrically insulating conductive sites present in different layers. Examples of the conductive sites include metal interconnects.

One embodiment of the semiconductor device of the invention will next be described.

As substrate 1, Si semiconductor substrates such as Si substrate and SOI (Si On Insulator) substrate can be employed. Alternatively, it may be a compound semiconductor substrate such as SiGe or GaAs.

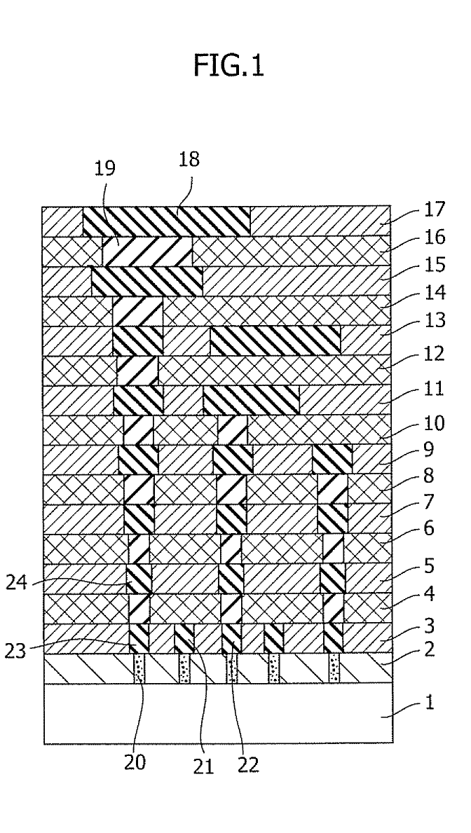

Interlayer insulating films illustrated in FIG. 1 are interlayer insulating film 2 of a contact layer, interlayer insulating films 3, 5, 7, 9, 11, 13, 15, and 17 of interconnect layers, and interlayer insulating films 4, 6, 8, 10, 12, 14, and 16 of a via layer.

The interconnect layers from the interlayer insulating film 3 of the bottom interconnect layer to the interlayer insulating film 17 of the uppermost interconnect layer are referred to as M1, M2, M3, M4, MS, M6, M7 and M8, respectively in the order from the bottom to the top. The layers from the lowermost interlayer insulating film 4 of the lowermost via layer to the interlayer insulating film 16 of the uppermost via layer are referred to as V1, V2, V3, V4, V5, V6 and V7, respectively in the order from the bottom to the top.

Some metal interconnects are indicated by numerals 18 and 21 to 24, respectively, but even if such a numeral is omitted, portions with the same pattern as that of these metal interconnects illustrate metal interconnects.

A via plug 19 is made of a metal and it is typically copper in the case of a copper interconnect. Even if a numeral is omitted, portions with the same pattern as that of these via plugs illustrate via plugs.

A contact plug 20 is connected to a gate of a transistor (not illustrated) formed on the uppermost surface of the substrate 1 or to the substrate.

As illustrated, the interconnect layers and the via layers are stacked alternately. The term “multilevel interconnects” typically means M1 and layers thereabove. The interconnect layers M1 to M3 are typically called local interconnects; the interconnect layers M4 to M5 are typically called intermediate or semi-global interconnects; and the interconnect layers M6 to M8 are typically called global interconnects.

In the semiconductor device illustrated in FIG. 1, the porous film of the invention is used as at least one of the interlayer insulating films 3, 5, 7, 9, 11, 13, 15, and 17 of the interconnect layers and the interlayer insulating films 4, 6, 8, 10, 12, 14 and 16 of the via layers.

When the porous film of the invention is used as the interlayer insulating film 3 of the interconnect layer (M1), a capacitance between the metal interconnect 21 and metal interconnect 22 can be reduced greatly.

When the porous film of the invention is used as the interlayer insulating film 4 of the via layer (V1), a capacitance between the metal interconnect 23 and metal interconnect 24 can be reduced greatly. Thus, use of the porous film of the invention having a low dielectric constant for the interconnect layers enables a drastic reduction of the capacitance between metal interconnects in the same layer. In addition, use of the porous film of the invention having a low dielectric constant for the via layers enables a drastic reduction in the capacitance between the metal interconnects above and below the via layer. Accordingly, use of the porous film of the invention for all the interconnect layers and via layers enables a great reduction in the parasitic capacitance of interconnects.

In addition, use of the porous film of the invention as an insulating film for interconnection is free from a conventional problem, that is, an increase in a dielectric constant caused by moisture absorption of porous films during formation of multilevel interconnects by stacking them one after another. As a result, the semiconductor device featuring high speed operation and low power consumption can be obtained.

In addition, due to high strength of the porous film of the invention, the semiconductor device thus obtained has improved mechanical strength. As a result, the semiconductor device thus obtained has greatly improved production yield and reliability.

The present invention will next be described specifically with Examples. It should be noted that the scope of the invention is not limited to or by these examples.

### PREPARATION EXAMPLES OF POLYSILOXANE COMPOUNDS BY HYDROLYSIS AND CONDENSATION REACTIONS USING A LARGE EXCESS OF WATER AND ACID CATALYST

### Preparation Example 1

A mixture of 45 g of methyltrimethoxysilane and 101 g of tetraethoxysilane was added, under stirring at room temperature, to a solution obtained by dissolving 0.18 g of concentrated nitric acid in 280 g of ultrapure water. The reaction mixture gradually generated heat and reached 50° C. but 30 minutes later, it returned to room temperature. Stirring was continued for 12 hours without changing the condition. To the reaction mixture was added 300 g of propylene glycol monomethyl ether acetate (which will hereinafter be referred to as PGMEA) and the low-boiling-point solvent was distilled off under reduced pressure. During this distillation, a bath of the evaporator was kept at 30° C. or less. To the remaining solution thus obtained were added 500 ml of toluene and 500 ml of ultrapure water. The resulting mixture was transferred to a separating funnel so as to remove a water layer. The organic layer was washed twice with 200 ml of ultrapure water. The organic layer thus obtained was distilled in an evaporator to remove the solvent therefrom, whereby 210 g of a solution was obtained as a mother solution of a polysiloxane compound. The solution had a nonvolatile residue of 20.3 mass % and had a weight average molecular weight, as measured by gel permeation chromatograph [GPC], of 3,062.

The ²⁹Si—NMR measurement of the sample was performed. As a result, it was found that molar ratios t1, t2, t3, q1, q2, q3 and q4 of the units represented by the above-described formulas (Q1 to Q4, T1 to T3) of the polysiloxane compound were 1%, 10%, 26%, 0%, 7%, 36%, and 19%, respectively, which resulted in following relationships:

(q1+q2+t1)/(q1+q2+q3+q4+t1+t2+t3)=0.08 and

(q3+t2)/(q1+q2+q3+q4+t1+t2+t3)=0.46.

### Preparation Example 2

In a similar manner to Preparation Example 1 except for the use of 0.11 g of concentrated sulfuric acid instead of nitric acid, synthesis was conducted, whereby 205 g of a concentrated solution was obtained. The resulting solution had a nonvolatile residue of 22.4 mass % and a weight average molecular weight, as determined by GPC, of 3,522. As a result of the ²⁹Si—NMR measurement of the sample, it has been found that the molar ratios t1, t2, t3, q1, q2, q3 and q4 were 1%, 14%, 23%, 1%, 12%, 36%, and 13%, respectively and calculation using these ratios resulted in the following relationships:

(q1+q2+t1)/(q1+q2+q3+q4+t1+t2+t3)=0.16 and

(q3+t2)/(q1+q2+q3+q4+t1+t2+t3)=0.50.

### Preparation Example 3

In a similar manner to Preparation Example 1 except for the use of 0.31 g of concentrated hydrochloric acid instead of nitric acid, synthesis was conducted, whereby 213 g of a concentrated solution was obtained. The resulting solution had a nonvolatile residue of 20.6 mass % and a weight average molecular weight, as determined by GPC, of 1,988. The ²⁹Si—NMR measurement of the sample was performed. As a result, it has been found that calculation based on the molar ratios t1, t2, t3, q1, q2, q3 and q4 leads to the following relationships:

(q1+q2+t1)/(q1+q2+q3+q4+t1+t2+t3)=0.12 and

(q3+t2)/(q1+q2+q3+q4+t1+t2+t3)=0.46.

### Preparation Example 4

In a similar manner to Preparation Example 1 except for the use of 0.33 g of methanesulfonic acid instead of nitric acid, synthesis was conducted, whereby 201 g of a concentrated solution was obtained. The resulting solution had a nonvolatile residue of 20.7 mass % and a weight average molecular weight, as determined by GPC, of 2,578. The ²⁹Si—NMR measurement of the sample was performed. As a result, it has been found that calculation based on the molar ratios t1, t2, t3, q1, q2, q3 and q4 leads to the following relationships:

(q1+q2+t1)/(q1+q2+q3+q4+t1+t2+t3)=0.08 and

(q3+t2)/(q1+q2+q3+q4+t1+t2+t3)=0.50.

### Preparation Example 5

In a similar manner to Preparation Example 1 except for the use of 0.15 g of perchloric acid instead of nitric acid, synthesis was conducted, whereby 227.15 g of a concentrated solution was obtained. The resulting solution had a nonvolatile residue of 21.8 mass % and a weight average molecular weight, as determined by GPC, of 3,570. The ²⁹Si—NMR measurement of the sample was performed. As a result, it has been found that calculation based on the molar ratios t1, t2, t3, q1, q2, q3 and q4 leads to the following relationships:

(q1+q2+t1)/(q1+q2+q3+q4+t1+t2+t3)=0.08 and

(q3+t2)/(q1+q2+q3+q4+t1+t2+t3)=0.47.

### Preparation Example 6

In a similar manner to Preparation Example 1 except for the use of 0.20 g of trifluoromethane instead of nitric acid, synthesis was conducted, whereby 227.50 g of a concentrated solution was obtained. The resulting solution had a nonvolatile residue of 18.4 mass % and a weight average molecular weight, as determined by GPC, of 2,869. The ²⁹Si—NMR measurement of the sample was performed. As a result, it has been found that calculation based on the molar ratios t1, t2, t3, q1, q2, q3 and q4 leads to following relationships:

(q1+q2+t1)/(q1+q2+q3+q4+t1+t2+t3)=0.07 and

(q3+t2)/(q1+q2+q3+q4+t1+t2+t3)=0.51.

Polysiloxane compounds satisfying the required properties relating to silanol and the like were obtained even if the kind of the acid catalyst was changed as described above.

### Comparative Preparation Example 1

### Example of Hydrolysis and Condensation Reactions in The Presence of an Acid Catalyst in a Conventional Manner

After 68 g (0.5 mole) of methyltrimethoxysilane, 152 g (1.0 mole) of tetramethoxysilane, 230 g of propylene glycol monopropyl ether and 120 g of methyl isobutyl ketone were charged in a 5-L flask, 180.02 g (11.0 mole) of water was added dropwise in 1 hour in the presence of 0.5 g of a maleic acid catalyst to hydrolyze the alkoxysilane. After the dropwise addition, the reaction mixture was stirred at 60° C. for 2 hours to complete the reaction. The acidic components were then neutralized. Methanol thus generated was distilled off under reduced pressure and the residue was concentrated to give a solid content of about 20 wt %. The resulting polysiloxane compound had a weight average molecular weight, as determined by GPC, of 940.

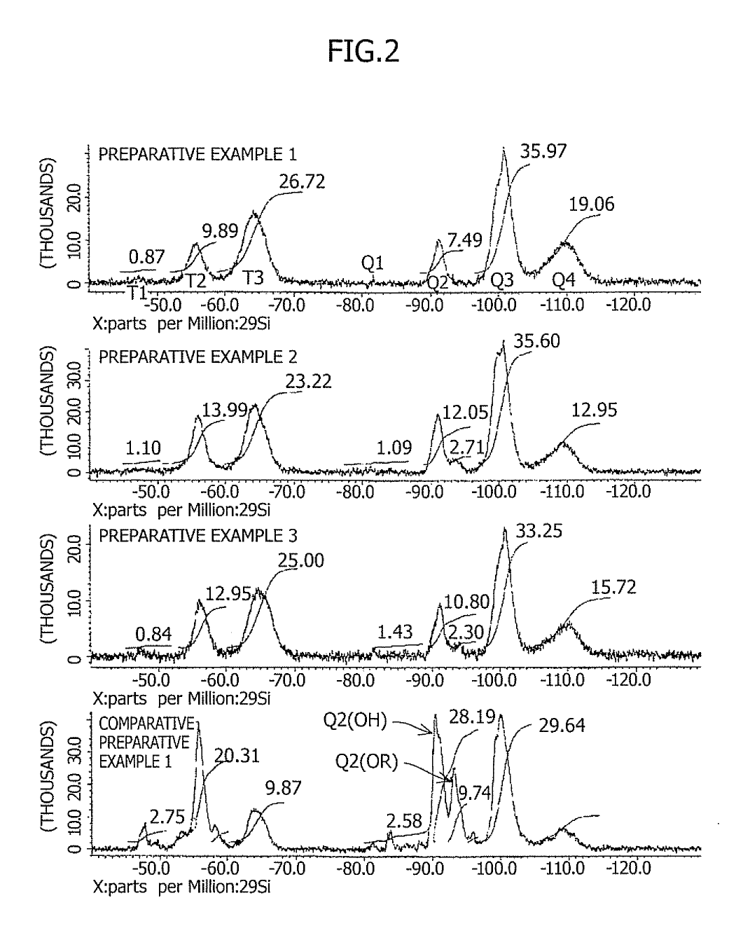

The ²⁹Si—NMR spectrum of the polysiloxane compound thus obtained is shown in FIG. 2, Proportions of units T-1, T-2, and T-3 were 8 mole %, 62 mole % and 30 mole %, respectively, based on the total units T of the siloxane resin thus obtained, while those of units Q-1, Q-2, Q-3, and Q-4 were 4 mole %, 42 mole %, 44 mole % and 10 mole %, respectively, based on the total units Q. It was also confirmed that 35% of the unit Q-2 remained as a methoxy group.

### Comparative Preparation Example 2

### Example of Hydrolysis and Condensation Reactions in the Presence of a Conventional Acid Catalyst

After 136.3 g (1.0 mole) of methyltrimethoxysilane, 304.4 g (2.0 mole) of tetramethoxysilane, 550 g of propylene glycol monopropyl ether and 240 g of methyl isobutyl ketone were charged in a 5-L flask, 360.04 g (22.0 mole) of water was added dropwise in the presence of 1 g of a maleic acid catalyst while keeping the internal temperature at 30° C. or less, while the alkoxysilane was hydrolyzed. After the dropwise addition, the reaction mixture was stirred at 60° C. for 2 hours. Viscosity of the reaction mixture gradually increased and the reaction was then terminated.

### (²⁹Si—NMR Measurement)

²⁹Si—NMR measurement was performed using “JNM-EPP-300” (300 MHz) manufactured by JEOL, Ltd. For measurement, acetone-d₆ was added to the sample solutions obtained in Preparation Examples. Results of Preparation Examples 1 to 3 and Comparative Preparation Example 1 are shown in FIG. 2 as typical measurement examples. In the spectra, each signal appearing at near δ −47, −56, −64, −83, −91, −100 and −109 belongs to Si in the structures T1, T2, T3, Q1, Q2, Q3 and Q4, respectively. It has been found that compared with the polysiloxane compound obtained in the process of Comparative Preparation Example, the polysiloxane compounds obtained in the process of Preparation Examples are evidently rich in components making the structures of T3, Q3 and Q4 rigid. Moreover, among the broad peaks, a peak derived from Si (silanol group) to which an alkoxy group is bonded appears on a higher magnetic field side than a peak derived from Si to which a hydroxyl group is bonded. For example, peaks at δ −89 to −95 in the spectrum of Comparative Preparation Example are derived from Q2 as described above and among these peaks the peak at −93 is derived from silicon substituted with an alkoxy group. From a peak area ratio, about 35% of the unit Q2 is an alkoxy-substituted silicon having low reactivity. In Preparation Examples, on the other hand, alkoxy-substituted silicon has almost disappeared.

### (Preparation of a Mother Solution for Adding Zeolite-Containing Fine Particles)

### Preparation Example 7

A mixture of 14.6 g of tetraethoxysilane and 25.4 g of a 1 mol/L aqueous solution of tetrapropylammonium hydroxide was stirred at room temperature for 3 days. The reaction mixture was then stirred at 75° C. for 12 hours to yield a colorless zeolite sol. The particle size of the resulting sol was measured using a submicron particle size distribution analyzer (measurement limit: 3 nm), resulting in failure because the particle size distribution extending to 5 nm prevented measurement of the whole particle size distribution. After 8 g of a 25 mass % aqueous solution of tetramethylammonium hydroxide, 512 g of ultrapure water, 960 g of ethanol and the zeolite sol were mixed at room temperature, 32 g of tetraethoxysilane and 24 g of methyltrimethoxysilane were added dropwise to the resulting mixture at 60° C. for 8 hours. Immediately after completion of the dropwise addition, a 20 mass % aqueous solution of maleic acid was added. To the resulting mixture was added 320 g of propylene glycol monopropyl ether, followed by concentration until the mass of the solution became 320 g. Ethyl acetate was then added. The mixture was washed twice with ultrapure water and then separated into layers. The ethyl acetate was distilled off under reduced pressure to obtain a mother solution for adding zeolite-containing fine particles. The resulting solution had a nonvolatile residue of 20.5 mass %.

### Preparation Example 8

A mixture of 14.6 g of tetraethoxysilane and 25.4 g of a 1 mol/L aqueous solution of tetrapropylammonium hydroxide was stirred at room temperature for 3 days. The reaction mixture was then stirred at 75° C. for 12 hours to yield a colorless zeolite sol. The particle size of the sol was measured using a submicron particle size distribution analyzer (measurement limit: 3 nm), resulting in failure because the particle size distribution extending to 5 nm prevented measurement of the whole particle size distribution. After 8 g of a 25 mass % aqueous solution of tetramethylammonium hydroxide, 512 g of ultrapure water, 960 g of ethanol and the zeolite sol were mixed at room temperature, 32 g of tetraethoxysilane and 24 g of methyltrimethoxysilane were added dropwise to the resulting mixture at 60° C. for 12 hours. Immediately after completion of the dropwise addition, a 20 mass % aqueous solution of maleic acid was added. To the resulting mixture was added 320 g of propylene glycol monopropyl ether, followed by concentration until the mass of the solution became 320 g. Ethyl acetate was then added. The mixture was washed twice with ultrapure water and then separated into layers. The ethyl acetate was distilled off under reduced pressure to obtain a mother solution for adding zeolite-containing fine particles. The resulting solution had a nonvolatile residue of 21.8 mass %.

### Preparation Example 9

A mixture of 14+6 g of tetraethoxysilane and 25.4 g of a 1 mol/L aqueous solution of tetrapropylammonium hydroxide was stirred at room temperature for 3 days. The reaction mixture was then stirred at 75° C. for 12 hours to yield a colorless zeolite sol. The particle size of the sol was measured using a submicron particle size distribution analyzer (measurement limit: 3 nm), resulting in failure because the particle size distribution extending to 5 nm prevented measurement of the whole particle size distribution. After 8 g of a 25 mass % aqueous solution of tetramethylammonium hydroxide, 512 g of ultrapure water, 960 g of ethanol and the zeolite sol were mixed at room temperature, 32 g of tetraethoxysilane and 24 g of methyltrimethoxysilane were added dropwise to the resulting mixture at 60° C. for 22 hours. Immediately after completion of the dropwise addition, a 20 mass % aqueous solution of maleic acid was added. To the resulting mixture was added 320 g of propylene glycol monopropyl ether, followed by concentration until the mass of the solution became 320 g. Ethyl acetate was then added. The mixture was washed twice with ultrapure water and then separated into layers. The ethyl acetate was distilled off under reduced pressure to obtain a mother solution for adding zeolite-containing fine particles. The resulting solution had a nonvolatile residue of 19.9 mass %.

### (Preparation of a Mother Solution for Adding Polysiloxane Fine Particles)

### Preparation Example 10

A solution obtained by mixing 188.4 g of ethanol, 93.44 g of ultrapure water, and 8.26 g of 25% tetramethylammonium hydroxide was heated to 60° C. under stirring. To the reaction mixture was added dropwise a mixture of 19+5 g of methyltrimethoxysilane and 36.43 g of tetraethoxysilane over 6 hours. After the reaction mixture was cooled to room temperature with ice water, 2 g of oxalic acid and 200 ml of PGMEA were added. The solvent was distilled off from the resulting solution by an evaporator until the residue became 161 g. To the solution thus obtained were added 200 g of ethyl acetate and 120 g of ultrapure water. The mixture was washed in a separating funnel and then left to stand. The water layer thus separated was removed, while the organic layer was washed twice with 120 ml of ultrapure water. After 120 ml of PGMEA was added to the organic layer thus obtained, the solvent was distilled off by an evaporator until the residue became 208 g. The concentrated solution thus obtained was provided as a mother solution for adding polysiloxane fine particles. The solution had a nonvolatile residue of 21.3 mass %.

### Preparation Example 11

In a similar manner to Preparation Example 10 except that the silane raw material was added dropwise over 4 hours instead of 6 hours, synthesis was conducted, whereby 204 g of a concentrated solution was obtained. The resulting solution had a nonvolatile residue of 22.9 mass %.

### Preparation Example 12

In a similar manner to Preparation Example 10 except that the silane raw material was added dropwise over 1 hour instead of 6 hours, synthesis was conducted, whereby 214 g of a concentrated solution was obtained. The resulting solution had a nonvolatile residue of 18.9 mass %.

### Preparation Example 13

In a similar manner to Preparation Example 10 except that the silane raw material was added dropwise over 1 hour instead of 6 hours and an amount of the aqueous solution of tetramethylammonium hydroxide was changed to 16.5 g, synthesis was conducted, whereby 188 g of a concentrated solution was obtained. The resulting solution had a nonvolatile residue of 21.00 mass %.

### (Preparation of a Porous-Film-Forming Composition)

### Example 1

A porous-film-forming composition was obtained by adding 4.6 g of the mother solution of a polysiloxane compound prepared in Preparation Example 1 to 92 g of the mother solution for adding zeolite-containing fine particles synthesized in Preparation Example 9.

### Example 2

A porous-film-forming composition was obtained by adding 9.2 g of the mother solution of a polysiloxane compound prepared in Preparation Example 1 to 92 g of the mother solution for adding zeolite-containing fine particles synthesized in Preparation Example 9.

### Example 3

A porous-film-forming composition was obtained by adding 13 g of the mother solution of a polysiloxane compound prepared in Preparation Example 1 to 92 g of the mother solution for adding zeolite-containing fine particles synthesized in Preparation Example 9.

### Example 4

A porous-film-forming composition was obtained by adding 18 g of the mother solution of a polysiloxane compound prepared in Preparation Example 1 to 92 g of the mother solution for adding zeolite-containing fine particles synthesized in Preparation Example 9.

### Example 5

A porous-film-forming composition was obtained by adding 8 g of the mother solution of a polysiloxane compound prepared in Preparation Example 1 to 92 g of the mother solution for adding polysiloxane fine particles synthesized in Preparation Example 10.

### Example 6

A porous-film-forming composition was obtained by adding 11 g of the mother solution of a polysiloxane compound prepared in Preparation Example 1 to 89 g of the mother solution for adding polysiloxane fine particles synthesized in Preparation Example 11.

### Example 7

A porous-film-forming composition was obtained by adding 15 g of the mother solution of a polysiloxane compound prepared in Preparation Example 1 to 85 g of the mother solution for adding polysiloxane fine particles synthesized in Preparation Example 12.

### Comparative Example 1

A comparative composition was obtained by adding 8 g of the mother solution of a polysiloxane compound prepared in Comparative Preparation Example 1 to 92 g of the mother solution for adding polysiloxane fine particles synthesized in Preparation Example 10.

### (Film Formation)

### (Zeolite-Containing Composition)

### Examples 8 to 11 and Comparative Examples 2 to 4

In Examples 8 to 11, the porous-film-forming compositions obtained in Examples 1 to 4 were used as were, respectively. In Comparative Examples 2 to 4, on the other hand, the mother solutions for adding zeolite-containing fine particles obtained in Preparation Examples 7 to 9 were used as were, respectively, as a film forming composition without adding thereto a polysiloxane compound. For application and heating at 120° C. and 230° C., a spin coater “DSPN-60” (trade name; product of Dainippon Screen) was used. Each of the compositions was applied onto a silicon wafer at a rotation speed of 4000 rpm and then sintered at 120° C. for 2 minutes, at 230° C. for 2 minutes, and at 425° C. for one hour in a sintering furnace “AVF-601” (trade name; product of Dainippon Screen), whereby a porous film of about 30 nm thick was obtained.

### (Composition Containing Silica Fine Particles)

### Examples 12 to 14 and Comparative Examples 5 to 9

In Examples 12 to 14, the porous-film-forming compositions obtained in Examples 5 to 7 were used as were, respectively. In Comparative Examples 5 to 8, on the other hand, the mother solutions obtained in Preparation Examples 10 to 13 were used as were, respectively, as a film forming composition. In Comparative Example 9, the comparative composition of Comparative Example 1 obtained by hydrolysis and condensation reactions in the presence of an acid catalyst in a conventional manner was used as the polysiloxane compound. The compositions were each applied onto a silicon wafer, followed by heating at 120° C. for 2 minutes, at 230° C. for 2 minutes and at 425° C. for 1 hour, whereby a porous film was obtained.

### (Measurement of Physical Properties)

The dielectric constant of each of the films thus obtained was measured using “495-CV System” (product of SSM Japan) in accordance with C—V measurements with an automatic mercury probe. The modulus of elasticity (mechanical strength) was measured using a nano indenter (product of Nano Instruments).

The measurement results of the dielectric constant and mechanical strength of each film are shown in Table 1.

TABLE 1

| | Porous-film forming composition | | | | | | |
|---|---|---|---|---|---|---|---|
| | Mother solution for adding | | | Mother solution of a | | | |
| | silicon-oxide-based fine particles | | | polysiloxane compound | | Porous film | |
| | Silicon | Preparation | | Preparation | | | Modulus of |
| | oxide-based | of mother | Amount | of mother | Amount | Dielectric | elasticity |
| | fine particles | solution | (g) | solution | (g) | constant | (GPa) |
| Ex. 8 | Zeolite | Prep. Ex. 9 | 92 | Prep. Ex. 1 | 4.6 | 2.33 | 6.05 |
| Ex. 9 | fine | Prep. Ex. 9 | 92 | | 9.2 | 2.45 | 8.19 |
| Ex. 10 | particles | Prep. Ex. 9 | 92 | | 13 | 2.59 | 9.87 |
| Ex. 11 | | Prep. Ex. 9 | 92 | | 18 | 2.85 | 11.02 |
| Comp. Ex. 2 | | Prep. Ex. 7 | — | — | — | 2.65 | 7.88 |
| Comp. Ex. 3 | | Prep. Ex. 8 | — | — | — | 2.49 | 6.66 |
| Comp. Ex. 4 | | Prep. Ex. 9 | — | — | — | 2.23 | 4.08 |
| Ex. 12 | Silica | Prep. Ex. 10 | 92 | Prep. Ex. 1 | 8 | 2.4 | 7.6 |
| Ex. 13 | fine | Prep. Ex. 11 | 92 | | 11 | 2.48 | 8.79 |
| Ex. 14 | particles | Prep. Ex. 12 | 89 | | 15 | 2.69 | 11.53 |
| Comp. Ex. 5 | | Prep. Ex. 10 | — | — | — | 2.17 | 3.9 |
| Comp. Ex. 6 | | Prep. Ex. 11 | — | — | — | 2.35 | 5.7 |
| Comp. Ex. 7 | | Prep. Ex. 12 | — | — | — | 2.5 | 7.23 |
| Comp. Ex. 8 | | Prep. Ex. 13 | — | — | — | 2.82 | 11.21 |
| Comp. Ex. 9 | | Prep. Ex. 10 | 92 | Comp. | 8 | 2.42 | 6.3 |
| | | | | Prep. Ex. 1 | | | |

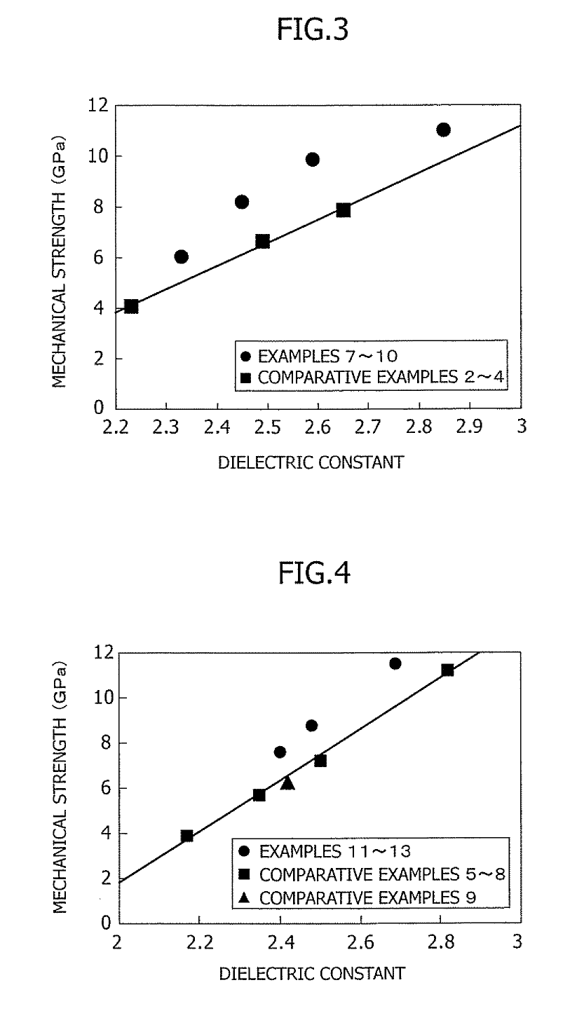

FIG. 3 shows a relationship between a dielectric constant and mechanical strength of a porous film formed using a composition prepared by adding a polysiloxane compound to each kind of zeolite-containing fine particles, wherein the polysiloxane compound is obtained by hydrolysis and condensation reactions in the presence of an acid catalyst by using a large excess of water. The relationship is plotted against a trade-off line (which will be descried later) of a film obtained without adding the polysiloxane compound.

FIG. 4 shows a relationship between a dielectric constant and mechanical strength of a porous film formed using a composition prepared by adding a polysiloxane compound obtained by hydrolysis and condensation reactions in the presence of an acid catalyst by using a large excess of water to each kind of silica fine particles, which relationship is plotted against a trade-off line (which will be descried later) of a film obtained without adding the polysiloxane compound.

An approximation curve in FIGS. 3 and 4 was obtained by the least square fitting method.

In FIGS. 3 and 4, a trade-off line between a dielectric constant and mechanical strength of a porous film formed using a composition containing only silicon-oxide-based fine particles is shown because of the following reason.

In a design of a low-dielectric-constant insulating film, it is only necessary to increase the porosity in order to reduce its dielectric constant, for example, by adjusting the particle size of particles contained in the composition so as to raise void ratio or using a pore-forming agent such as porogen. If a filmis fairly uniform and made of the same material, a portion having a skeleton material provides mechanical strength so that with an increase in porosity, the mechanical strength lowers. This means that there is a trade-off relationship between a dielectric constant and mechanical strength. In fact, there is a trade-off relationship between a dielectric constant and mechanical strength of porous films formed by adjusting the particles under conditions so as to change only the porosity without appreciably changing the material. They show even a linear relationship in a narrow range (a range of dielectric constant from 2.1 to 2.7). The term “trade-off line” as used herein means this relationship.

In order to evaluate whether a new material is a low-dielectric-constant film having high mechanical strength or not, it is necessary to find at the same value of dielectric constant whether the mechanical strength of the material is higher than that of a conventional material. As illustrated in FIGS. 3 and 4, it is therefore necessary to confirm where the relationship between a dielectric constant and mechanical strength of the new material exists relative to the trade-off line.

As described above, FIG. 3 shows a trade-off line (mechanical strength expected from dielectric constant) of known materials. Plotted are the dielectric constant and mechanical strength of the films formed using compositions containing only known zeolite-containing silicon-oxide-based fine particles. Their dielectric constant and mechanical strength were controlled by changing the surface modification time of zeolite without changing the material system. On the other hand, data of films obtained using compositions prepared by adding a polysiloxane compound, which has been prepared in the presence of an acid by hydrating silanol with an excess of water to prevent gelation, to silicon-oxide-based fine particles containing one kind of zeolite while changing the amount of the polysiloxane compound are plotted relative to the trade-off line. As a result, the data each lies above the trade-off line, suggesting that compared with the relationship between dielectric constant and mechanical strength of the film formed using only zeolite-containing silicon-oxide-based fine particles, the film of the invention has higher mechanical strength at the same value of dielectric constant and is therefore superior in physical properties.

It has been found from FIG. 4 that the dielectric constant and mechanical strength of the compositions containing only polysiloxane fine particles synthesized in the presence of an alkaline catalyst in a conventional manner can be adjusted by changing the conditions for preparing fine particles without changing the materials, and there is a linear trade-off relationship between dielectric constant and mechanical strength. When a polysiloxane compound prepared using a large amount of water and acid catalyst is added to polysiloxane fine particles, the data lie above the trade-off line similar to FIG. 3. It has also been found that the mechanical strength value is higher at every dielectric constant values than that expected from a specific dielectric constant on the trade-off line.

When a polysiloxane compound prepared using an acid catalyst in a conventional manner is added (Comparative Example 9), the absolute value of mechanical strength increases, but the dielectric constant also increases proportionately. This suggests that mechanical strength is not improved as expected from the dielectric constant and the composition of Comparative Example 9 is not as effective as the composition of the invention for improving the mechanical strength relative to dielectric constant.

### Examples 15 to 19

It was verified as described below whether the films obtained by the compositions containing each polysiloxane compound of Preparation Examples 2 to 6 respectively different acid catalysts had similar performances to films available from a composition using the polysiloxane compound of Preparation Example 1.

The compositions were prepared in a similar manner to Example 12 except for the change of the kind of the polysiloxane compound. The amount of the mother solution of each of the polysiloxane compounds was adjusted so that the dry weight of it became equal to that of the polysiloxane compound of Preparation Example 1 used in Example 12. After film formation as in Example 12, physical properties of the film were measured.

The results are shown in Table 2.

TABLE 2

| | Porous-film forming composition | | | | | | |
|---|---|---|---|---|---|---|---|
| | Mother solution for adding | | | | | | |
| | silicon-oxide-based fine | | | Mother solution of a | | | |
| | particles | | | polysiloxane compound | | Porous film | |
| | Silicon- | Preparation | | Preparation | | | Modulus of |
| | oxide-based | of mother | Amount | of mother | Amount | Dielectric | elasticity |
| | fine | solution | (g) | solution | (g) | constant | (GPa) |
| Ex. 12 | Silica | Prep. Ex. 10 | 92 | Prep. Ex. 1 | 8 | 2.4 | 7.6 |
| Ex. 15 | fine | Prep. Ex. 10 | 92 | Prep. Ex. 2 | 7.5 | 2.41 | 7.69 |
| Ex. 16 | particles | Prep. Ex. 10 | 92 | Prep. Ex. 3 | 7.9 | 2.4 | 7.59 |
| Ex. 17 | | Prep. Ex. 10 | 92 | Prep. Ex. 4 | 7.9 | 2.4 | 7.58 |
| Ex. 18 | | Prep. Ex. 10 | 92 | Prep. Ex. 5 | 7.5 | 2.39 | 7.41 |
| Ex. 19 | | Prep. Ex. 10 | 92 | Prep. Ex. 6 | 8.8 | 2.42 | 7.86 |

The physical properties of the porous films thus obtained did not differ largely from those of the porous film obtained in Example 12. It was therefore confirmed that the film forming compositions had almost similar performances without being affected by a change in the kind of the acid.

It is to be understood that the present invention is not limited to the embodiments given above. The embodiments given above are merely illustrative, and those having substantially the same configuration as the technical concept defined by the appended claims of the present invention and having similar functions and effects are considered to fall within the technical scope of the present invention.

1. A composition for forming a porous film comprising: silicon-oxide-based fine particles; and a polysiloxane compound capable of forming a silicon-oxygen-silicon bond between the fine particles through condensation during film formation, thereby improving the strength of a skeleton formed by the silicon-oxide-based fine particles.

2. A composition for forming a porous film according to claim 1, wherein the polysiloxane compound is obtained by hydrolysis and condensation reactions, in the presence of an acid catalyst, of a hydrolyzable silane compound containing at least one tetrafunctional alkoxysilane compound represented by the following formula (1):
Si(OR¹)₄ (1)
wherein, R¹s may be the same or different and each independently represents a linear or branched C₁₋₄ alkyl group and/or at least one alkoxysilane compound represented by the following formula (2):
R²ₙSi(OR³)₄₋ₙ (2)
wherein, R²(s) may be the same or different when there are plural R²s and each independently represents a linear or branched C₁₋₈ alkyl group, R³(s) may be the same or different when there are plural R³s and each independently represents a linear or branched C₁₋₄ alkyl group, and n is an integer from 1 to 3, while hydrating a silanol group generated during the reaction so as to control the condensation reaction and suppress gelation.

3. A composition for forming a porous film according to claim 2, wherein the hydrolysis and condensation reactions are performed so that the hydrolysis reaction mixture constantly contains water in an amount exceeding a molar equivalent of the hydrolyzable group in the hydrolysable silane compound which has already been charged.

4. A composition for forming a porous film according to claim 2, wherein water required for hydrolysis and condensation reactions performed while suppressing gelation is at least 5 moles per mole of the hydrolyzable group in the hydrolyzable silane compound.

5. A composition for forming a porous film according to claim 1, wherein the polysiloxane compound has units represented by the following formulas Q1 to Q4, and T1 to T3: 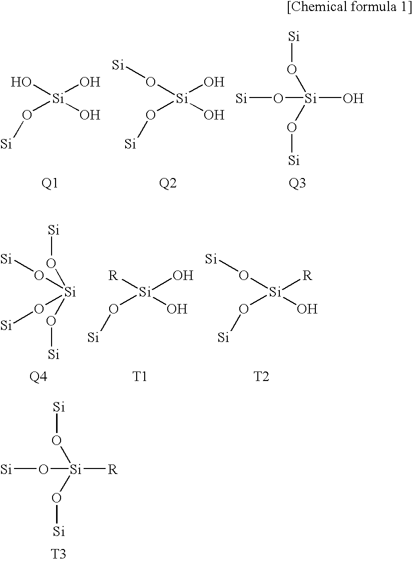
wherein, Q means a unit derived from a tetravalent hydrolyzable silane, T means a unit derived from a trivalent hydrolyzable silane, and R in T1 to T3 means that a bond represented by Si—R is a bond between silicon and a carbon substituent and supposing that molar ratios of the units in the polysiloxane compound are q1, q2, q3, q4, t1, t2 and t3, respectively, they satisfy the following relationships (1) and (2):
(q1+q2+t1)/(q1+q2+q3+q4+t1+t2+t3)≦0.2 (1)
(q3+t2)/(q1+q2+q3+q4+t1+t2+t3)≧0.4 (2)

6. A composition for forming a porous film according to claim 1, wherein the silicon-oxide-based fine particles are zeolite fine particles including zeolite seed crystals.

7. A composition for forming a porous film according to claim 6, wherein the zeolite fine particles are obtained by modifying zeolite with a hydrolyzable silane as a crosslinkable side chain.

8. A composition for forming a porous film according to claim 1, wherein the silicon-oxide based fine particles are silica fine particles.

9. A composition for forming a porous film according to claim 8, wherein the silica fine particles are obtained by hydrolysis and condensation reactions, in the presence of an alkaline catalyst, of a hydrolyzable silane compound containing at least one tetrafunctional alkoxysilane compound represented by the following formula (3):
Si(OR⁴)₄ (3)
wherein, R⁴s may be the same or different and each independently represents a linear or branched C₁₋₄ alkyl group and at least one alkoxysilane compound represented by the following formula (4):
R⁵ₘSi(OR⁶)₄₋ₘ (4)
wherein, R⁶(s) may be the same or different when there are plural R⁶s and each independently represents a linear or branched C₁₋₄ alkyl group, R⁵(s) may be the same or different when there are plural R⁵s and each independently represents a linear or branched C₁₋₈ alkyl group, and m is an integer from 1 to 3.

10. A composition for forming a porous film according to claim 9, wherein the alkaline catalyst is a mixture of at least one hydrophilic basic catalyst selected from the group consisting of alkali metal hydroxides and quaternary ammonium hydroxides represented by the following formula (5):
(R⁷)₄N⁺OH⁻ (5)
wherein, R⁷s may be the same or different and each independently represents an organic group composed of carbon, hydrogen and oxygen and the cationic portion [(R⁷)₄N⁺] satisfies the following relationship (6):
(N+O)/(N+O+C)≧⅕ (6)
in which, N, O and C are the numbers of nitrogen, oxygen and carbon atoms contained in the cationic portion, respectively, and at least one hydrophobic basic catalyst selected from quaternary ammonium hydroxides which do not satisfy the above-described relationship (6).

11. A composition for forming a porous film according to claim 9, wherein as at least a portion of the alkaline catalyst, a salt of a silsesquioxane cage compound represented by the following formula (7):
(SiO_{1.5}—O)ₚ^{p-}(X⁺)ₚ (7)
wherein, X represents NR¹³₄, R¹³ may be the same or different and each independently represents a linear or branched C₁₋₄ alkyl group and p is an integer from 6 to 24 which has been prepared in advance is used.

12. A porous film obtained by applying a porous-film-forming composition of claim 1 to a substrate and sintering the applied substrate.

13. A method for forming a porous silicon-containing film, which comprises applying the porous-film-forming composition of claim 1 to a substrate to form a thin film and sintering the thin film.

14. A semiconductor device, which comprises, as a low-dielectric-constant insulating film, a porous silicon-containing film obtained by applying the composition of claim 1 to a substrate and then sintering the applied substrate.

15. A method for manufacturing a semiconductor device, which comprises the steps of:
applying the composition of claim 1 onto a substrate having a metal interconnect layer to form a thin film; and
sintering the thin film to form a porous film.

16. A method for preparing a composition for forming a porous film, comprising the steps of:
obtaining a polysiloxane compound by performing hydrolysis and condensation reactions, in the presence of an acid catalyst, of a hydrolyzable silane compound containing at least one tetrafunctional alkoxysilane compound represented by the following formula (1):
Si(OR¹)₄ (1)
wherein, R¹s may be the same or different and each independently represents a linear or branched C₁₋₄ alkyl group and/or at least one alkoxysilane compound represented by the following formula (2):
R²ₙSi(OR³)₄₋ₙ (2)
wherein, R²(s) may be the same or different when there are plural R²s and each independently represents a linear or branched C₁₋₈ alkyl group, R³(s) may be the same or different when there are plural R³s and each independently represents a linear or branched C₁₋₄ alkyl group, and n is an integer from 1 to 3 in the reaction mixture containing water in an amount sufficient for hydrating a silanol group generated during the reaction to control the condensation reaction and suppress gelation;
extracting the polysiloxane compound in an organic solvent; and
mixing the polysiloxane compound thus extracted and silicon-oxide-based fine particles.
